(19) United States
(12) Patent Application Publication
(10) Pub. No.: US 2026/0299200 A1
(43) Pub. Date: Oct. 1, 2026

(54) PHOTONIC SUBSTRATE PREPARATION METHOD AND PHOTONIC WAVEGUIDE PREPARATION OR FABRICATION METHOD

(71) Applicant: ECOLE POLYTECHNIQUE FEDERALE DE LAUSANNE (EPFL), Lausanne (CH)

(72) Inventors: Marta DIVALL, Gingins (CH); Zheru QIU, Crissier (CH); Rui Ning WANG, Morges (CH); Tobias KIPPENBERG, St-Sulpice (CH); Xinru JI, Ecublens (CH)

(21) Appl. No.: 19/478,018

(22) PCT Filed: Apr. 19, 2024
(86) PCT No.: PCT/IB2024/053818

§ 371 Date: Oct. 23, 2025

(30) Foreign Application Priority Data
Apr. 25, 2023 (EP) 23169810.1

(51) Int. Cl. G02B 6/13; G02B 6/12; H10P 36/20

(52) U.S. Cl. CPC G02B 6/13; H10P 36/20; G02B 2006/12169

(57) ABSTRACT

Photonic integrated circuit optical waveguide device preparation or fabrication method comprising providing a silicon substrate, depositing at least one copper gettering silicon nitride layer or material, depositing at least one optical waveguide cladding layer or material, forming at least one optical waveguide or optical waveguide structure and thermally annealing the at least one silicon substrate after the formation of the at least one optical waveguide or optical waveguide structure on the at least one silicon substrate to remove hydrogen impurities or hydrogen-related impurities from the at least one optical waveguide, and to capture or trap copper impurities of the at least one silicon substrate in the at least one copper gettering silicon nitride layer or material.

### CROSS-REFERENCE TO RELATED APPLICATIONS

The present application claims priority to the European Application EP23169810.1 that was filed on Apr. 25 2023, the entire contents thereof being herewith incorporated by reference.

### FIELD OF THE INVENTION

The present invention relates to a substrate preparation method as well as a substrate produced or prepared by this method. The present invention more particularly concerns a photonic device substrate preparation method, or a photonic integrated circuit (PIC) substrate preparation method and substrates or structures produced or prepared by these methods. The present invention also relates to a photonic integrated circuit optical waveguide device preparation or fabrication method.

### BACKGROUND

Scientific literature has to date widely reported that the dominant source of optical loss in silicon nitride waveguides emanates from scattering losses. Etching processes applied during waveguide fabrication produce waveguide wall roughness resulting in optical scattering losses.

The research group to which the Inventors belong has previously achieved a world record-low-loss value for integrated silicon nitride waveguides at the value of 0.5 dB/m using a reflow process that assures the provision of smoother device walls (see Pfeiffer, M. H. P. et al, Ultra-smooth silicon nitride waveguides based on the Damascene reflow process: fabrication and loss origins, Optica 5, 884-892 (2018)).

Another known source of loss in these devices stems from hydrogen impurities known to be present in significant quantities (>10²⁰ atoms/cm³) in the Si₃N₄ core material and the SiO₂ cladding material that are deposited by chemical reactions using hydrogen based chemistry (for example, dichlorosilane, or silane).

A strong absorption peak of OH bonds can, for example, be present around 1380 nm with a long absorption tail extending to longer wavelengths. This notorious absorption peak originates from the hydrogen impurity introduced by the commonly used silicon precursors such as SiH₄, SiH₂Cl₂, and Si(OC₂H₅)₄ (TEOS) in deposition processes such as chemical vapor deposition processes.

However, this source of loss is systematically eliminated or significantly reduced by these optical waveguide devices undergoing annealing to remove residual hydrogen and provide low loss waveguide devices and low loss PICs based on silicon nitride.

Nevertheless, in view of loss values measured in optical fibers (0.2 dB/km), in theory three orders of magnitude better performance could be achieved also in integrated photonic waveguides and PICs.

While previous material analysis measurements had shown some presence of transition metals such as Cr, Fe, and Cu in silicon nitride material of the waveguide structure (see Pfeiffer, M. H. P. et al. Ultra-smooth silicon nitride waveguides based on the Damascene reflow process: fabrication and loss origins. Optica 5, 884-892 (2018)), the exact amounts present were unable to be determined from the mass spectrometry method used, and as a result, this did not permit to determine the degree of significance of these impurities on absorption losses in the device. Moreover, the absorbance of transition metal ions depends on their valence state, which is generally unknown.

Additionally, thin-film deposition tools, currently used for the fabrication of waveguides, produce and deposit highly pure materials used for the waveguide cladding and core such as SiO₂ and Si₃N₄ materials and any presence of transition metals is not expected to be significant, likely lower than the detection limits of known measurement methods and thus likely still to be unmeasurable.

Additionally, the silicon wafers upon which these optical devices are fabricated are crystalline and ultra-pure wafers used in the microelectronics industry. The quantity of transition metals such as Cu in these wafers is often not specified because the quantity present is so low that it is below the level, that can be detected.

Consequently, efforts are focusing on reducing scattering losses, still considered the dominant source of optical loss in silicon nitride waveguides, to provide reduced overall losses with a view to achieving the same performance already measured in optical fibers.

Surprisingly, the Inventors found that optical losses of their fabricated waveguide devices were not being lowered, and in cases where the optical loss was expected to remain constant and be similar to identical previously produced devices, the optical loss measured was instead increasing.

The inventors carried out various different optical loss measurement methods endeavoring to understand the observed unexpected optical loss behavior of their devices.

The Inventors used one particular measurement method that permits to quantify a thermal absorption loss of the Si₃N₄ waveguides. This involves a linear response measurement and allows to separate the losses caused by absorption from other loss mechanisms (details of the measurement setup can be found in Liu, J., Huang, G., Wang, R. N. et al, High-yield, wafer-scale fabrication of ultralow-loss, dispersion-engineered silicon nitride photonic circuits, Nature Commun. 12, 2236(2021)).

Briefly, the Inventors characterize the resonance frequency shift response of the probe mode induced by intensity modulation of the pump mode, which is tuned to the resonance of the fabricated cavity. This intensity modulation causes a change in the intracavity photon number of the pump mode, which modulates the resonance frequency of the probe mode via Kerr and thermal nonlinearities. By analyzing the measured response one calibrates the absorption loss of the pump resonance. A typical measurement with the resonances measured at different frequencies is shown in FIGS. 3A and 3B. This method exploits the fact that the thermal response dominates at low frequency (short dash), while the Kerr response dominates at higher frequency (3 dashed).

The Inventors carried out these measurements for a number of different silicon nitride waveguide devices that were fabricated at different times.

Additionally, the Inventors performed secondary ion mass spectrometry (SIMS) on these different silicon nitride waveguide devices to analyze their material composition at different depths into the device.

During SIMS analysis, the sample surface is slowly sputtered away by an ion beam, while recording information as a function of depth, called the depth profile. Depth resolution depends on flat bottom craters. The first 70 nm depth can contain materials due to surface contamination and sputtering. The instrument provides uniform sputter currents by sweeping a finely focused primary beam in a raster pattern over a square area. All measurements shown in the Figures are performed averaged over a 20 micrometer×20 micrometer area, as shown for example in FIG. 4 inside a micro-resonator ring of one of the silicon nitride waveguide devices investigated. The areas of the optical devices where the above-mentioned absorption measurements were performed contain 2 μm wide waveguides and filling pattern structures, both made out of Si₃N₄. These areas are too small to do direct sputtering on only the areas where Si₃N₄ is present. The measurements were therefore averaged over the Si₃N₄ area and the surrounding silicon-oxide. The Si₃N₄ to SiO₂ ratio content was 1:3.

Bombardment of a sample surface with a primary ion beam followed by mass spectrometry of the emitted secondary ions was carried out to perform SIMS and to determine the possible presence and quantity of impurities. The spectrum is specific to the ions extracted. A 10¹⁶ atoms/cm³ resolution is expected from the full metal contamination analysis. The presence of Cu was determined by the Inventors. A full spectral analysis excluded the contribution of other metal contaminants. Cu specific measurements, using a different spectrometer, gave a resolution around 9·10¹⁴ atoms/cm³.

The SIMS measurements performed on the optical devices allowed to determine a measurement of optical losses as a function of ‘copper’ contamination density.

To gain clarity over the level of Cu contamination on a more quantitative level, additional samples were created with homogeneous blanket layers to assure better exclusion of the SiO₂ material in the measurement. SIMS measurements performed on the blanket layers allowed to investigate contamination at different stages of fabrication as well as the effect of annealing. The measurements permitted the Inventors to conclude that Cu in the Si₃N₄ waveguide material was surprisingly the relevant source of the observed optical loss and the optical loss behavior observed in different optical devices fabricated at different times. This was determined based on SIMS measurements taken from selected optical chips determined to have different loss values and allowed to demonstrate and quantify the correlation between absorption losses and Cu content.

FIG. 5 shows some resulting measurements performed on three of optical chips, fabricated with the standard damascene process (described in the above mentioned references). Absorption loss values versus Cu concentration measured by SIMS is shown for three samples (D48, D81, D96) fabricated at different times. FIG. 5 shows a clear correlation between the measured thermal absorption loss and the measured Cu concentration with the surprisingly increased presence of Cu in the Si₃N₄ waveguide material of devices D81 and D96 resulting in an increase in loss values.

FIG. 6 shows SIMS measurement results performed on these samples D48 and D96 that permitted to determine the level of copper contamination in the Si₃N₄ layer. For the D48 sample, due to the low level of copper concentration a higher resolution measurement was performed compared to that of D96.

Measurements performed by the Inventors on the above-mentioned additional samples having blanket silicon nitride embedded in silicon oxide on a silicon carrier wafer, as well as similar thickness dimensions as used in the Inventor's standard waveguide device fabrication process (without structures over the surface) surprising demonstrated copper concentration in the silicon nitride material to increase as a result of annealing.

FIG. 7 shows the measurement results before and after an exemplary and standard 11 hour annealing at a temperature of 1200° C. The Cu impurity concentration level increases to reach nearly 10¹⁸ atoms/cm³, a level detrimental for optical performance which prevents the formation of solitons in microcavities of the optical devices. Annealing is on the other hand necessary in order to drive out hydrogen, which also causes absorption losses.

Further investigations by the Inventors involved directly depositing silicon nitride on a bare silicon wafer to determine whether the material deposition tool itself might be at the origin of the contamination. SIMS measurement was then performed for all metals (and therefore at higher resolution limit). Annealing was then carried out, and the Inventors subsequently performed a high resolution SIMS measurement for copper only. FIG. 8 shows the SIMS measurements results. The Cu concentration clearly increased in the deposited silicon nitride layer as a result of heating the sample for the standard 11 hours at a 1200° C. temperature. The concentration level reaches nearly 3×10¹⁷ atoms/cm³ after annealing. The results indicate that the material deposition tool is not at the origin of the Cu contamination. Surprisingly, despite the wafer being a high purity microelectronics industry-grade silicon wafer, the silicon wafer is determined to be the source of Cu contamination of the silicon nitride material. The annealing process appears to result in diffusion of Cu from the silicon wafer to the silicon nitride material, and thus to the waveguide of the optical devices.

It is highly counter-intuitive that microelectronic industry grade silicon wafers, in which copper content is often below detection limits of suppliers, would be a dominant source of optical loss in silicon nitride waveguides, which seems to have been preventing development in integrated photonic waveguides and PICs towards the low optical loss values of optical fibers.

Indeed, an optical loss mechanism is created in the optical devices by an annealing process carried out to remove another optical loss mechanism that is the presence of hydrogen impurities.

The Inventors thus have surprisingly found that optical losses observed in their optical devices were correlated to the presence of copper that entered the critical active region of the optical devices and the silicon nitride waveguides from the silicon wafer during device annealing to remove hydrogen impurities. The generally presumed and relatively small quantity of copper present in underlying support wafers seems to be displaced and relocated to the active waveguide region of the optical device, the area of the device where the presence of such an impurity is least desired. Elimination of hydrogen impurities in the silicon nitride waveguide results in the formation of a high concentration of another unwanted impurity, and a removed source of light loss is replaced with another.

A goal of the present invention is to provide a solution to this inconveniences, and in particular, to provide a method and substrate that assures a reduced impurity contamination in the active region of the optical device fabricated using that substrate and permits to reduce light loss in the optical device.

### SUMMARY

It is therefore one aspect of the present disclosure to provide a substrate preparation method, in particular, a photonic device substrate preparation method or a photonic integrated circuit substrate preparation method that addresses the above-mentioned inconveniences and needs.

It is another aspect of the present disclosure to provide an optical device or optical waveguide device preparation or fabrication method, or a photonic integrated circuit optical device or optical waveguide device preparation or fabrication method that addresses the above-mentioned inconveniences and needs.

The optical waveguide device preparation or fabrication method assures the provision of an optical waveguide device of reduced light loss due to a reduced impurity contamination, in particular, a reduced Cu impurity contamination in the active region of the optical device fabricated.

The present disclosure provides a photonic integrated circuit optical waveguide device preparation or fabrication method for reducing copper impurity optical loss in at least one optical waveguide or optical waveguide structure of the photonic integrated circuit optical waveguide device, the at least one optical waveguide or optical waveguide structure comprising a silicon nitride waveguide core. The method may comprise providing at least one silicon substrate, depositing at least one copper gettering silicon nitride layer or material on the at least one silicon substrate, depositing at least one optical waveguide cladding layer or material on the at least one copper gettering silicon nitride layer or material that is deposited on the at least one silicon substrate, forming at least one optical waveguide or optical waveguide structure comprising at least one elongated silicon nitride waveguide core provided on and supported by the at least one optical waveguide cladding layer or material that is deposited on the at least one copper gettering silicon nitride layer or material which is deposited on the at least one silicon substrate, the at least one elongated silicon nitride waveguide core being supported by or being at least partially embedded by the at least one optical waveguide cladding layer or material; and thermally annealing the at least one silicon substrate after the formation of the at least one optical waveguide or optical waveguide structure on the at least one silicon substrate to remove hydrogen impurities or hydrogen-related impurities from the at least one optical waveguide, and to capture or trap copper impurities of the at least one silicon substrate in the at least one copper gettering silicon nitride layer or material.

The photonic device substrate or photonic integrated circuit substrate preparation method may comprise providing at least one silicon substrate, forming at least one copper impurity enriched layer or material on the at least one silicon substrate by heating or annealing the at least one silicon substrate, polishing at least one silicon oxide layer provided on the at least one silicon substrate, the at least one silicon oxide layer being provided on the at least one silicon substrate prior to heating or annealing the at least one silicon substrate, the at least one silicon oxide layer being heated or annealed during the formation of the at least one copper impurity enriched layer or material, the polishing of the at least one silicon oxide layer providing at least one polished silicon oxide surface, and depositing at least one further silicon oxide layer onto the at least one polished silicon oxide surface to provide a device fabrication structure or substrate for fabrication of a photonic waveguide device.

Alternatively, the photonic device substrate or photonic integrated circuit substrate preparation method may comprise providing at least one silicon substrate, forming at least one copper impurity enriched layer or material on the at least one silicon substrate by heating or annealing the at least one silicon substrate, and removing the at least one copper impurity enriched layer or material containing copper impurities transferred through the at least one silicon substrate to provide a decontaminated substrate and a device fabrication structure for fabrication of an photonic waveguide device.

The present disclosure provides substrate preparation methods to prevent copper diffusing into the photonics integrated circuits, either by gettering copper from the wafer substrate or by introducing additional steps into the fabrication to diffuse copper into layers, not significant for the photonics.

The substrate preparation method permits to produce an active region of an optical device that has a reduced transition metal content or a reduced copper content (for example, an ultra-low copper content), or that is (substantially) transition metal-free or (substantially) copper-free.

The substrate preparation method in particular permits to produce a silicon nitride active region of an optical device that has a reduced transition metal content or a reduced copper content (for example, an ultra-low copper content), or that is (substantially) transition metal-free or (substantially) copper-free.

The method permits to create ultra-low loss photonic integrated circuits based on silicon nitride that do not have copper contaminants, or that are substantially copper contaminant-free.

Unpublished research results by the Inventors show an origin of optical losses to be correlated to the presence of copper, and an accumulation of copper that enters the silicon nitride waveguides during annealing which are part of every process-flow for the fabrication of ultra-low loss silicon nitride PICs, in order to remove hydrogen.

The invention provides a method to avoid the accumulation of copper in the optically active region and in particular in silicon nitride waveguide layers, and provides viable solutions that are not included to date in the manufacturing of photonic integrated circuits.

The Inventors findings and proposed solution are unusual in that the technical problem is non-intuitive, and surprising in view of the fact that the origin of the copper impurity in the silicon nitride waveguide does not come from the numerous processing steps performed in the cleanroom (including reactive ion etching, cleaning baths, wafer handling etc.) but rather from the anneals that cause copper to diffuse from the silicon wafer, and through the oxide cladding into the silicon nitride. In other words, the specific technical problem addressed by the present disclosure was itself an unrecognized technical problem until now. Indeed, it was only through extensive research and by being able to arrive at the understanding that the anneals were causing the accumulation of copper coming from microelectronic high purity grade silicon wafers, where copper content is often below detection limit of the suppliers, could the solution of the present disclosure be determined.

The Inventors findings and proposed solution are unusual in that it is found that even microelectronic wafers that are crystalline and ultra-pure cause significant accumulation of copper (>10¹⁶ atoms/cm³) in silicon nitride layers upon annealing.

The methods of the present disclosure can advantageously be adopted in any foundry.

The present disclosure also concerns the provision of an optical device or optical waveguide device preparation or fabrication method, or a photonic integrated circuit optical device or optical waveguide device preparation or fabrication method that addresses the above-mentioned inconveniences and needs. Such methods may use a substrate or structure produced or provided by the substrate preparation method.

Specific embodiments and other advantageous features can be found in the dependent claims.

The present disclosure also concerns a substrate or structure produced or provided by the substrate preparation method. This device fabrication substrate or structure can subsequently be used for the fabrication of photonic or optical devices, such as waveguides.

Thermal absorption is reduced in subsequently fabricated optical waveguides produced on these device fabrication substrates or substrates, which resolves the current problem of high thermal absorption that prevents the formation of solitons. This reduced thermal absorption is highly advantageous, for example, for the generation of solitons and chip-scale frequency combs.

The above and other objects, features and advantages of the present invention and the manner of realizing them will become more apparent, and the invention itself will best be understood from a study of the following description with reference to the attached drawings showing some preferred embodiments of the invention.

### BRIEF DESCRIPTION OF THE DRAWINGS

The accompanying drawings, which are incorporated herein and constitute part of this specification, illustrate the presently preferred embodiments of the invention, and together with the general description given above and the detailed description given below, serve to explain features of the invention.

FIG. 1A shows an exemplary substrate preparation method according to the present disclosure.

FIG. 1B shows a substrate including a gettering layer or gettering material according to one exemplary embodiment of the present disclosure.

FIG. 2A shows another exemplary substrate preparation method according to the present disclosure.

FIG. 2B shows an annealing step of the substrate preparation method of the embodiment illustrated in FIG. 2A, carried out, for example, after deposition of the barrier layer and the silicon oxide layer.

FIG. 2C shows a polishing step of the substrate preparation method of the embodiment illustrated in FIG. 2A.

FIG. 2D shows the resulting structure following the polishing step illustrated in FIG. 2C.

FIG. 2E shows a device fabrication structure or device fabrication substrate produced following deposition of silicon oxide on the polished surface of the structure of FIG. 2D, and that can then be used for optical device fabrication.

FIG. 2F shows yet another exemplary embodiment of the substrate preparation method according to the present disclosure.

FIGS. 3A and 3B show the result of absorption loss measurements carried out on an optical chip (D96 sample) comprising a silicon nitride waveguide microresonator, fabricated in the conventional way without any particular substrate preparation.

FIG. 4 is a microscope image of a sputtered sample area at the center of the micro-resonator ring of the photonic chip.

FIG. 5 shows a graph of measured absorption losses Cu concentration measured by secondary ion mass spectrometry (SIMS) for three different device samples fabricated at different times.

FIG. 6 shows secondary ion mass spectrometry (SIMS) measurements measured from two different photonic chips (D48 and D96 photonic chips).

FIG. 7 shows secondary ion mass spectrometry (SIMS) measurements, before and after annealing, that show an increase of a copper concentration in a silicon nitride layer embedded into silicon oxide after annealing.

FIG. 8 shows secondary ion mass spectrometry (SIMS) measurements, before and after annealing, showing an increase in copper concentration in a silicon nitride layer deposited directly on a silicon wafer.

FIG. 9 shows a reduction in copper concentration via gettering into a silicon nitride layer. The concentration level has reached an average of 1.5×10¹⁶ atoms/cm³, which is about an order of magnitude lower than the level measured in the silicon nitride deposited on the standard silicon wafer.

FIG. 10 shows the exemplary substrate preparation method of FIGS. 1A and 1B, and from which comparative Cu content measurements are presented in FIG. 9.

FIG. 11A shows further details of the substrate preparation method of FIGS. 2A to 2E.

FIG. 11B shows a SIMS measurement of a structure or chip fabricated according to the method of FIGS. 2A to 2E and 11A, in which a silicon nitride gettering barrier layer is provided below a thicker silicon oxide layer, which is used in the preparation of Si₃N₄ photonic devices, and shows an increased level of copper in the barrier layer but not in the Si₃N₄ photonic device.

FIG. 12 shows the reduced optical loss in waveguide devices fabricated on the decontaminated substate produced by the method of the present disclosure.

FIGS. 13A to 13C show an exemplary photonic integrated circuit optical waveguide device preparation or fabrication method according to the present disclosure.

FIGS. 14A to 14D show an exemplary embodiment of the photonic integrated circuit optical waveguide device preparation or fabrication method of FIGS. 13A to 13C.

FIGS. 15A to 15D show another exemplary embodiment of the photonic integrated circuit optical waveguide device preparation or fabrication method of FIGS. 13A to 13C.

FIG. 16 shows secondary ion mass spectrometry (SIMS) measurements to detect copper (Cu) impurities across different layers of the fabricated device of FIG. 15C. The measurement results show a substantial concentration of Cu in the gettering silicon nitride layer, exceeding the concentration in other device layers by an order of magnitude. This finding highlights the effectiveness of the gettering layer in impurity sequestration and demonstrates the practical application and effectiveness of this approach in reducing metal impurity diffusion in photonic devices.

Herein, identical reference numerals are used, where possible, to designate identical elements that are common to the Figures. Also, the images are simplified for illustration purposes and may not be depicted to scale.

### DETAILED DESCRIPTION OF SEVERAL EMBODIMENTS

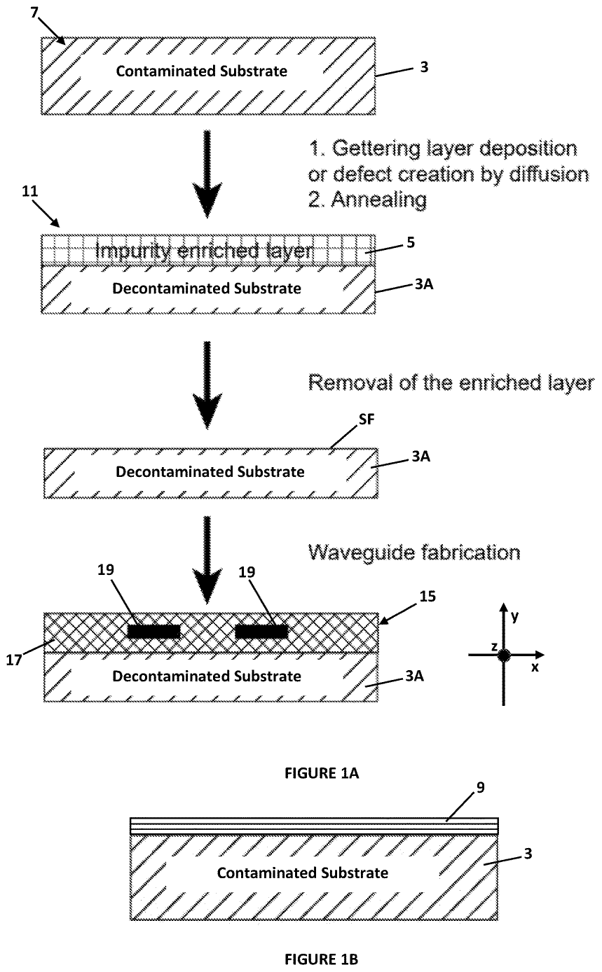

FIG. 1A shows an exemplary substrate or support layer preparation method, or a photonic device substrate preparation method, or a photonic integrated circuit substrate preparation method according to the present disclosure.

The method comprises providing at least one substrate or support layer 3. The substrate or support layer 3 can, for example, be subsequently used to fabricate devices such as optical or photonic devices (for example, waveguide devices), or to fabricate one or more photonic integrated circuits or optical chips. The present disclosure also concerns an optical device, optical waveguide device, or photonic integrated circuit optical waveguide device preparation or fabrication method using the substrate or support provided by the substrate or support layer preparation method.

The substrate 3 may comprise or consist of a silicon wafer, for example, a microelectronics industry-grade silicon wafer.

The silicon substrate or wafer 3 comprises or consists of a prime grade silicon wafer or substrate.

The substrate 3 comprises or consists of, for example, a non-reclaimed substrate and/or a device-free substrate and/or an electronic device-free substrate and/or an optical waveguide-free substrate. The silicon substrate 3 comprises or consists of, for example, a non-reclaimed silicon substrate and/or a device-free silicon substrate and/or an electronic device-free silicon substrate and/or an optical waveguide-free silicon substrate.

The substrate 3 is, for example, a contaminated substrate containing one or more contaminants or impurities whose removal is desired. The contaminants or impurities may include, for example, one or more transition metals. The contaminant or impurity may include, for example, copper Cu. The substrate 3 comprises or consist of copper contaminated silicon, or silicon containing Cu impurities.

The copper impurities comprise or consist of, for example, copper ions.

The copper of the copper impurities transferred through and/or from or out of the silicon substrate 3 (to, for example, a copper impurity enriched layer or material 5) is intrinsically present copper intrinsically present in the silicon substrate 3, and/or non-semiconductor manufacturing process introduced copper impurities. The copper impurities comprise or consist of copper impurities present in the silicon substrate 3 prior to the fabrication or provision of photonic or optical devices (such as at least one optical waveguide or optical waveguide structure) on the silicon substrate 3.

At least one impurity enriched layer or material 5 is formed on the substrate 3. This is done, for example, by heating or annealing the substrate 3. The at least one impurity enriched layer or material 5 that is formed on the substrate 3 is, for example, a copper impurity enriched layer or material 5.

The impurity enriched layer or material 5 is, for example, formed on the substrate 3 prior to the provision or deposition of one or more photonic or optical device materials on the substrate 3 (and/or prior to optical or photonic device fabrication (for example, an optical waveguide device)), such materials being used to define a photonic or optical device, or an active region thereof, or used to form a waveguide core or a directly contacting cladding material of a waveguide structure of the optical or photonic device (directly contacting a waveguide core).

The impurity enriched layer or material 5 can be, for example, formed on or in the substrate 3 at an upper and outer portion 7 thereof by impurity diffusion to the upper portion 7 of the substrate 3 during heating or annealing of the substrate 3. The impurity enriched layer or material 5 is, for example, formed within the volume or upper volume of the substrate 3.

Alternatively, the substrate 3 may be provided including at least one gettering layer or gettering material 9 provided on the substrate 3 (see, for example, FIG. 1B). The gettering layer or material 9 may, for example, be provided onto or deposited onto the substrate 3. The at least one gettering layer or gettering material 9 is, for example, at least one copper gettering layer or copper gettering material 9.

The gettering layer or material 9 is, for example, provided or deposited directly on the substrate 3.

The gettering layer or material 9 is, for example, provided or deposited on the substrate 3 prior to the provision or deposition of one or more photonic or optical device materials onto the substate 3 that are used to define a photonic or optical device, or an active region thereof, or used to form a waveguide core (or elongated waveguide core, in the z-direction, into page in FIG. 1A) or a directly contacting cladding material of a waveguide structure of the optical or photonic device.

The gettering layer or material 9 may, for example, comprises or consists of silicon nitride (for example, Si₃N₄), or a phosphorous doped layer or material. The phosphorous doped layer or material may, for example, be a phosphorus doped silicon layer or material, or a phosphorus doped silicon nitride layer or material, or a phosphorus doped silicon oxide layer or material. Silicon nitride may, for example, be deposited by low pressure chemical vapor deposition (LPCVD) or plasma enhanced chemical vapor deposition (PECVD). (See, for example, Jaeger, Richard C. (2001), “Thermal Oxidation of Silicon”. Introduction to Microelectronic Fabrication, Upper Saddle River: Prentice Hall, ISBN 978-0-201-44494-0, the entire contents of which are incorporated herein by reference).

The thickness of the deposited gettering layer or material 9 can be, for example, between 150 nm and 350 nm, or 200 nm and 350 nm (extremity values included).

The heating or annealing of the substrate 3 (with or without the gettering layer or material 9) can, for example, be carried out by heating of the substrate 3 in an oven or furnace, for example, in a controlled atmosphere, for example, a nitrogen atmosphere. However, different methods can be used, for example, annealing in a chlorine atmosphere.

The annealing temperature can, for example, be set to be above a recrystallization temperature of the substrate 3, and the substrate 3 is maintained in the oven at that temperature for a time duration that permits impurity displacement or diffusion to the upper and outer portion 7 of the substrate 3, or into the gettering layer or material 9.

For example, for a silicon substrate, annealing may for example be carried out for a duration of 4 hours at a temperature of, for example, 1000° C. The temperature may, for example, be ramped up to 1000° C. at a 10° C./min ramping rate.

However, it should be noted that this annealing temperature value and time duration are merely provided as exemplary values for silicon, the time duration may be longer, for example, between 10 and 35 hours, and the annealing temperature may, for example, be 1100° C. or 1200° C. These values can be adjusted in a manner permitting to optimize the impurity extraction and impurity displacement (for example, copper) to the upper and outer portion 7 of the substrate 3 or into the gettering layer or material 9.

The substrate 3 may, for example, be heated or annealed at a temperature between 400° C. and 1200° C., or between 900° C. and 1200° C., or between 400° C. and 1250° C., or between 600° C. and 1250° C., or between 900° C. and 1250° C. (extremity values included).

The substrate 3 may, for example, be heated or annealed for a time duration between 1 hour and 12 hours, or between 1 hour and 35 hours for either of the previous temperature ranges.

The substrate 3 may, for example, be heated or annealed at a temperature between (i) 800° C. or 1000° C. and (ii) 1250° C., and for a duration of between 2 hours and 35 or 60 hours.

The impurity enriched layer or material 5 is thus formed in the upper and outer portion or volume 7 of the substrate 3 by impurity displacement thereto. Alternatively, the impurity enriched layer or material 5 is, for example, formed on the substrate by the heating or annealing the substrate 3 comprising the gettering layer or material 9. The impurity enriched layer or material 5 comprises of consists of the gettering layer or material 9 into which impurities have been displaced and have accumulated.

The impurity enriched layer or material 5 is formed by heating or annealing the substrate 3 to transfer, for example, copper to the impurity enriched layer or material 5, or to the upper and outer portion 7 or to the gettering layer or material 9 to increase a quantity of copper of the impurity enriched layer or material 5, or of the upper and outer portion 7, or of the gettering layer or material 9.

Annealing results in a structure 11 being formed, the structure 11 comprising the impurity enriched layer or material 5 and the decontaminated substrate 3A, the decontaminated substrate 3A comprising the portion of the substate 3 from which impurities have been removed or that contains a relatively lower impurity content.

After annealing has been completed, the impurity enriched layer or material 5 containing impurities transferred through the substrate 3 is removed. That is, the upper and outer portion 7 of the substrate 3 is, for example, removed to provide the decontaminated substrate 3A, or the gettering layer or material 9 is, for example, removed to provide the decontaminated substrate 3A.

The decontaminated substrate 3A is thus provided or made available for use in the subsequently fabrication of optical devices that may be fabricated on a decontaminated substrate thus eliminating or reducing the risk that the fabricated optical devices become contaminated, for example, with copper impurity, and assuring the provision of optical devices having reduced optical loss stemming from absorption by impurities such as copper. The decontaminated substrate 3A is or forms a device fabrication substrate or structure 3A for fabrication of one or more photonic or optical devices, for example, an optical waveguide device.

The removal of the impurity enriched layer or material 5 may, for example, be carried out by etching, laser removal or by chemical-mechanical polishing CMP, sometimes called planarization.

Chemical mechanical polishing CMP is a process, which is a combination of chemical and mechanical forces. It can be described as a mixture of chemical etching and free abrasive polishing.

For example, a slurry comprising colloidal silica particles, for example about 50 nm in size, in an aqueous suspension can be used. When carrying out planarization, a speed during planarization can be defined by the rotational speed of the polishing head and table. In general, polishing occurs at a head speed of 60 rpm and table speed of 65 rpm. However, these speeds can vary and be adjusted during the polishing process, and the exact value of such parameters depend on, for example, the sample type or slurry used.

The slurry particles are then cleaned from the polished and/or planarized surface and, for example, any remaining material can be removed using etching such as a buffered oxide etch. After removal of the impurity enriched layer or material 5, one or more photonic or optical device materials can be deposited onto the substate 3 (decontaminated substrate 3A) to fabricate one or more photonic or optical devices 15, or to fabricate one or more photonic integrated circuits or optical chips 15 (see, for example, FIG. 1A).

For example, at least one cladding material 17 may be provided or deposited to form a cladding layer of a photonic device 15. At least one waveguide core material 19 may be provided or deposited to form a waveguide 19 embedded in the cladding layer 17. A further cladding layer may be deposited on the waveguide 19 to form an outer or passivation layer. For example, silicon oxide may be used as the cladding/passivation material and the optical waveguide may, for example, comprise or consist of silicon nitride (for example, Si₃N₄), rare earth ion implanted silicon nitride, for example, erbium-doped silicon nitride (for example, Er:Si₃N₄), lithium niobate LiNbO₃ or barium titanate BaTiO₃.

For example, a cladding material 17 such as SiO₂ may be deposited onto the decontaminated substrate 3A, structured or patterned, and silicon nitride Si₃N₄ then deposited onto the structured or patterned as SiO₂ as a waveguide core material 19. After removal of excess silicon nitride Si₃N₄ by, for example, planarization, further cladding material can optionally be deposited on top of the waveguide core material 19. Annealing may then be carried out to remove other impurities, such as hydrogen. Alternatively, a silicon nitride Si₃N₄ layer can be deposited on the cladding material 17 and patterned by photolithography to form one or more silicon nitride waveguides and further silicon oxide cladding material can be deposited on top of the patterned silicon nitride waveguide core material 19.

Optical waveguide devices 15 can be fabricated on the decontaminated substrate 3A using the Damascene process for example as described in U.S. Pat. No. 10,191,215 and in the previous references mentioned herein, the entire contents of each of which are incorporated herein by reference.

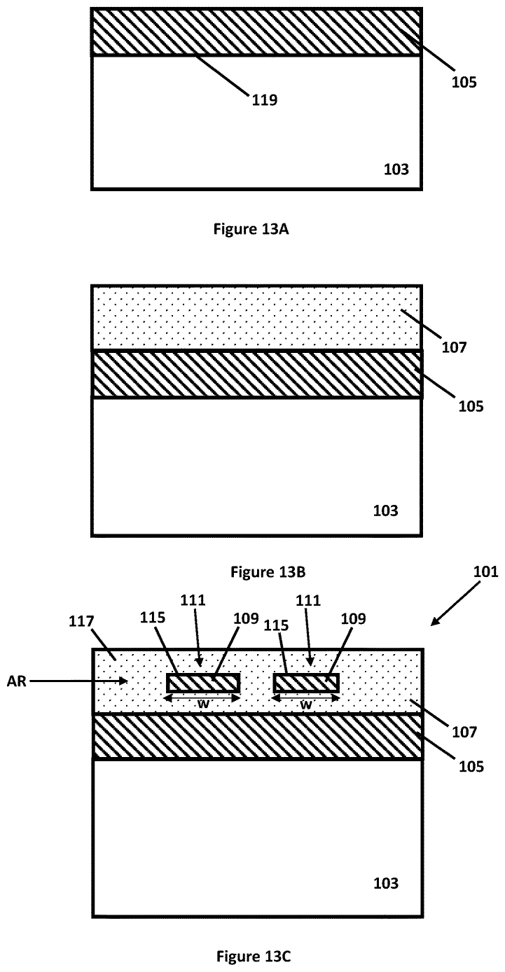

The optical waveguide or optical waveguide structure fabrication process described herein in relation to the embodiment of FIGS. 13 to 15 can also be used to fabricate optical waveguides or optical waveguide structures on the decontaminated substrate of the present exemplary embodiment as part of an optical device, optical waveguide device, or photonic integrated circuit optical waveguide device preparation or fabrication method.

FIG. 9 shows the reduction of the copper impurity concentration in a silicon nitride layer deposited directly on a decontaminated silicon wafer 3A after the gettering layer 9 was removed by CMP. The new silicon nitride layer was deposited and reannealed for a period of 33 h at 1200° C. By using the gettering layer 9, the copper content in the Si wafer 3 can thus be reduced.

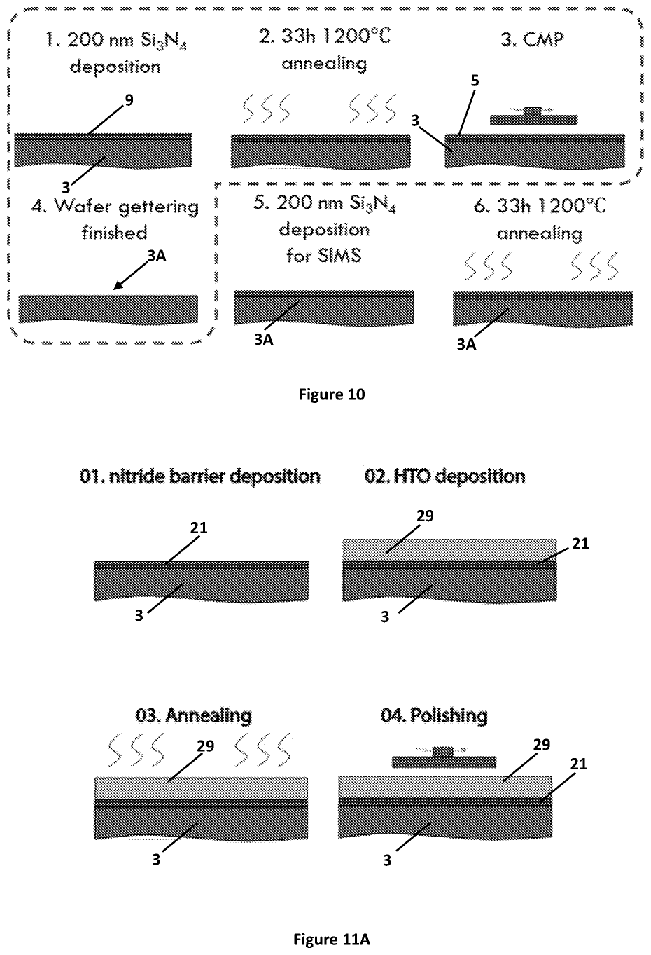

FIG. 10 shows different steps carried out to obtain the results shown in FIG. 9.

Silicon nitride material of a thickness between 200 nm and 350 nm (for example, 350 nm thickness (for example, in y-direction)) was directly deposited onto two identical bare silicon wafers 3 (step 1, FIG. 10) and annealed for three periods of a standard annealing time, which corresponds to 33 hours at 1200° C. (step 2, FIG. 10).

A first wafer 3 was then measured by high resolution SIMS in order to determine the copper content, while the second wafer was processed using chemical mechanical polishing (CMP) to remove the contaminated Si₃N₄ layer 5 (step 3, FIG. 10). Following this removal, the same silicon nitride material deposition was carried out and the same annealing was performed (33 h at 1200° C.) to verify the overall reduction of copper, and also to rule out the contamination via another source, for example, via the annealing tube.

FIG. 9 confirms the reduction in copper concentration via gettering over 33 h at 1200° C. into a 350 nm thick silicon nitride layer. The Cu level is reduced to reach an average of 1.5×10¹⁶ atoms/cm³, which is about an order of magnitude below the levels measured in the silicon nitride layer deposited on the first standard wafer. These results show that a decontaminated substrate, having a reduced copper content, can be obtained, thus permitting optical devices 15 of lower optical loss to be provided using these wafers 3A.

The present disclosure also concerns a decontaminated substrate 3A produced or provided by the above method. The present disclosure also concerns at least one photonic device, photonic chip or optical waveguide formed or fabricated on the decontaminated substrate 3A.

The at least one photonic device, photonic chip or optical waveguide formed or fabricated on the decontaminated substrate 3A has, for example, an average copper impurity quantity or concentration of less than 1×10¹⁷ atoms per cm², or less than 0.5×10¹⁷ atoms per cm², or less than 1×10¹⁷ atoms per cm².

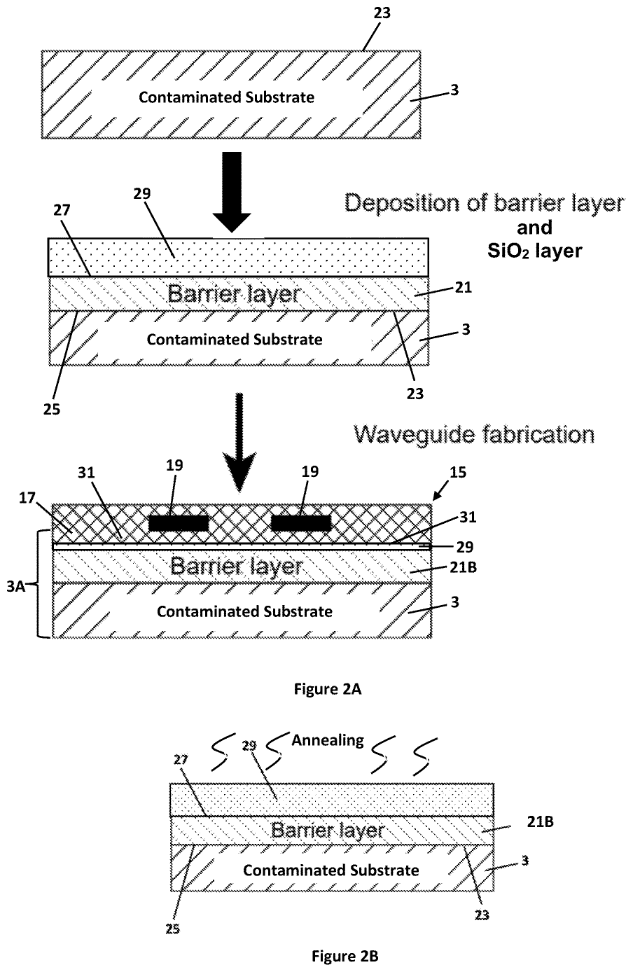

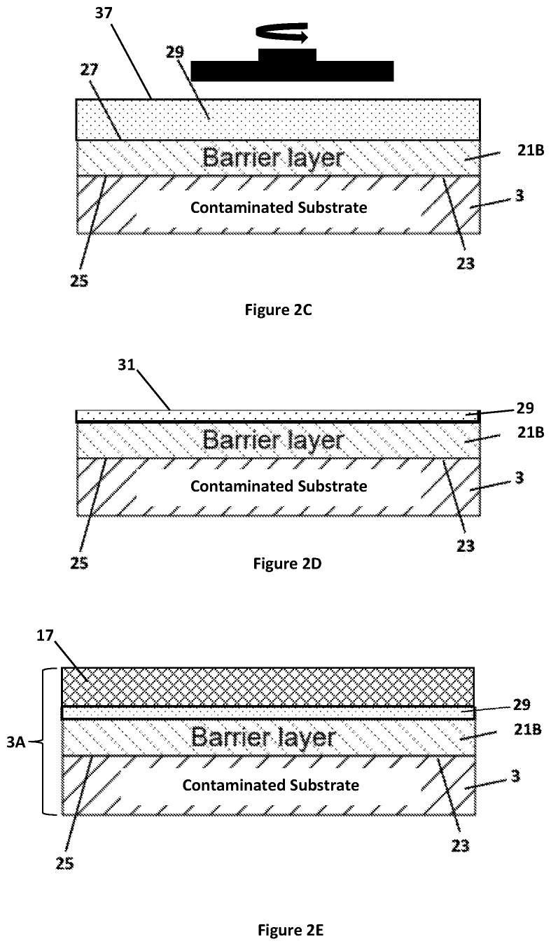

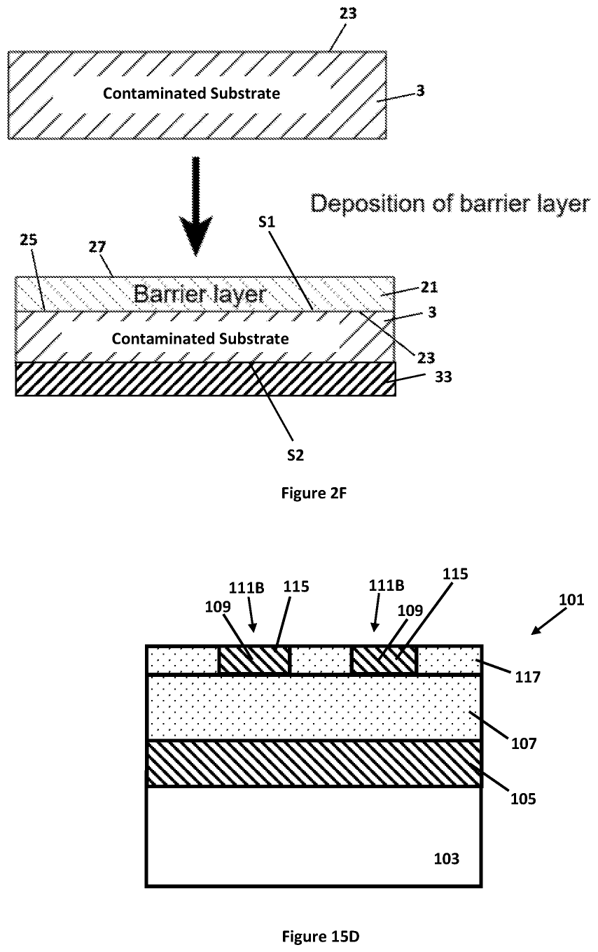

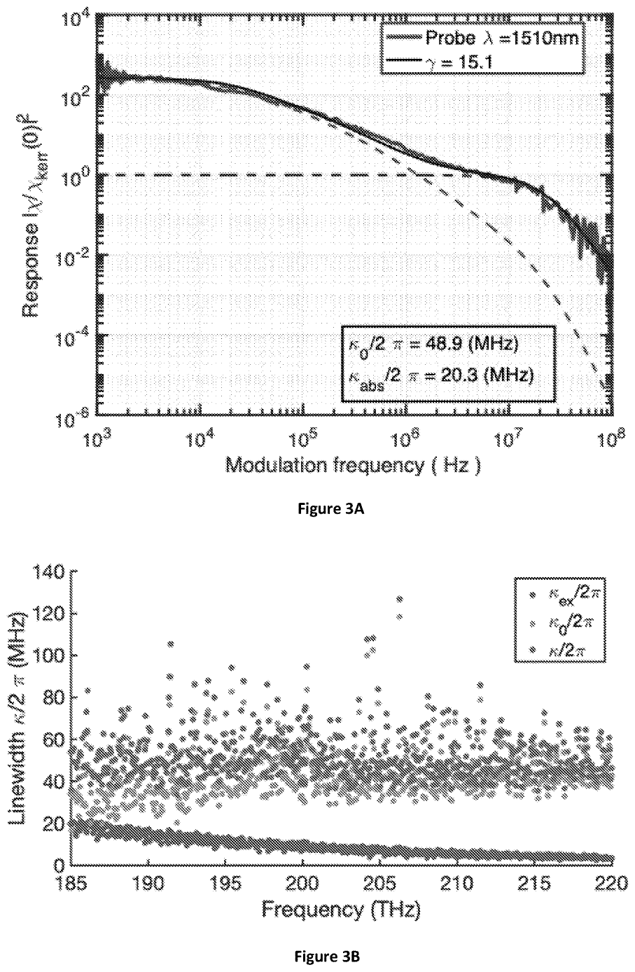

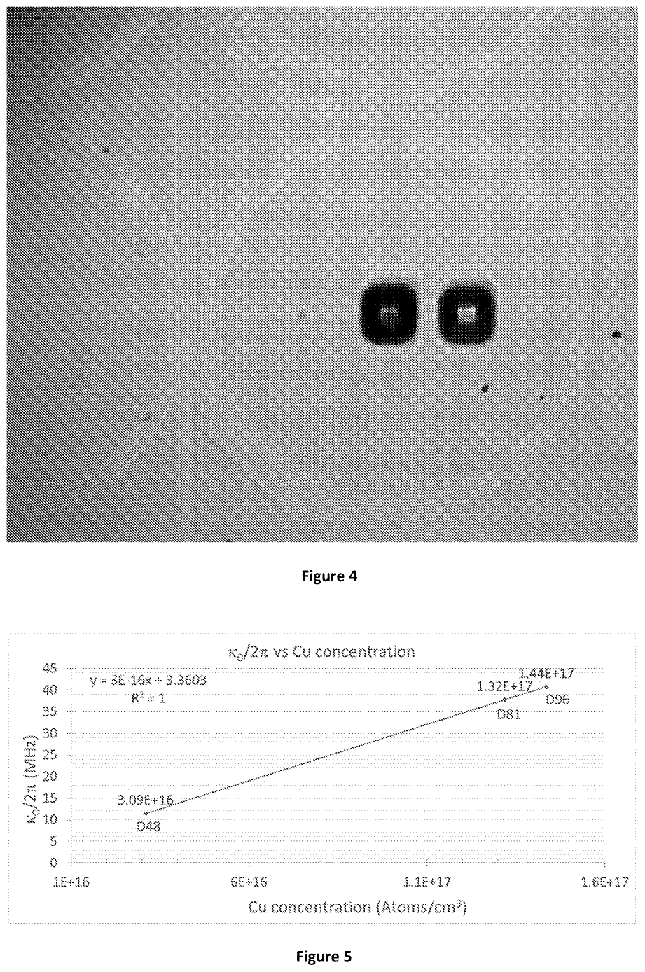

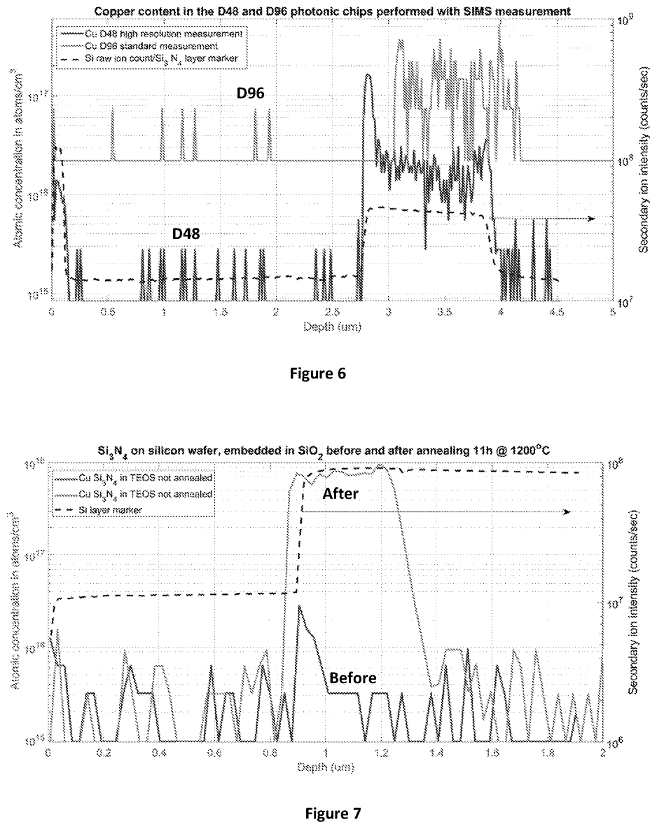

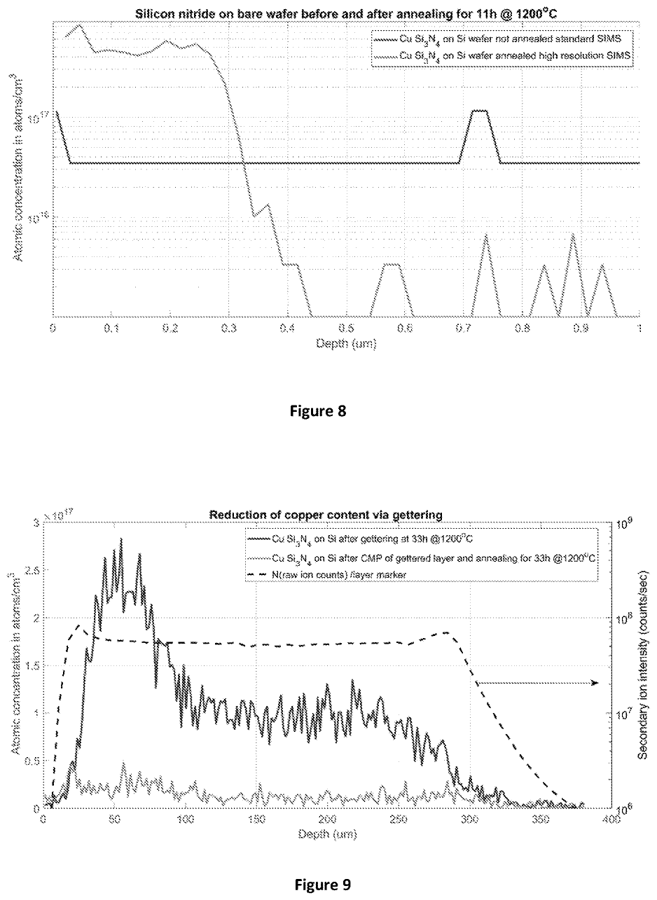

FIGS. 2A to 2E show another exemplary embodiment of a substrate or support layer preparation method, or a photonic device substrate preparation method, or a photonic integrated circuit substrate preparation method according to the present disclosure.

The present disclosure also concerns an optical device, optical waveguide device, or photonic integrated circuit optical waveguide device preparation or fabrication method using the substrate or support provided by the substrate or support layer preparation method.

The method comprises providing at least one substrate or support layer 3, which can be the substrate 3 described above in relation to the previous embodiment of FIGS. 1A and 1B.

The method comprises providing or depositing at least one impurity barrier layer or material 21 or at least one impurity gettering barrier layer or material 21 on the substrate 3, for example, on a first surface 23 of the substrate 3. The at least one impurity barrier layer or material 21 comprises or consists of at least one copper impurity barrier layer or material 21 or at least one copper impurity gettering barrier layer or material 21.

The impurity barrier layer or material 21 comprises a first surface 25 and a second surface 27 located opposite the first surface 25. The first surface 25 of the impurity barrier layer or material 21 contacts the first surface 23 of the substrate 3.

The impurity barrier layer or material 21 is, for example, configured to prevent impurities being transferred from the substrate 3 and through the impurity barrier layer or material 21 to the second surface 27 of the impurity barrier layer or material 21. The impurity barrier layer or material 21 is, for example, configured to getter impurities being transferred from the substrate 3 and into the impurity barrier layer or material 21.

The impurity barrier layer or material 21 is, for example, configured to prevent copper being transferred from the substrate 3 through the impurity barrier layer or material 21, or through the impurity barrier layer or material 21 to the second surface 27 of the impurity barrier layer or material 21 by gettering of the copper impurity or copper ions. A copper impurity enriched layer or material 21B is formed from or in the impurity barrier layer or material 21 by heating or annealing the at least one silicon substrate 3 and/or the impurity barrier layer or material 21.

The impurity barrier layer or material 21 is, for example, provided or deposited directly on the substrate 3. The first surface 25 of the impurity barrier layer or material 21, for example, directly contacts the first surface 23 of the substrate 3.

The first surface 25 of the impurity barrier layer or material 21 is located closer to the first surface 23 of the substrate 3 than the second surface 27 of the impurity barrier layer or material 21.

The impurity barrier layer or material 21 may, for example, comprises or consists of silicon nitride (for example, Si₃N₄), or a phosphorous doped layer or material.

The phosphorous doped layer or material may, for example, be a phosphorus doped silicon layer or material, or a phosphorus doped silicon nitride layer or material, or a phosphorus doped silicon oxide layer or material.

The impurity barrier layer or material 21 may, for example, have a thickness between 200 nm and 2000 nm, for example, 200 nm.

The impurity barrier layer or material 21 can be provided or deposited on the substate 3, for example, by low pressure chemical vapor deposition (LPCVD), or plasma enhanced chemical vapor deposition (PECVD).

At least one silicon oxide layer 29 is deposited onto the (copper) impurity gettering barrier layer 21, for example, directly onto the second surface 27 (FIG. 2A). Deposition may, for example, also be by low pressure chemical vapor deposition (LPCVD), or plasma enhanced chemical vapor deposition (PECVD), as well-known known to the skilled person in the art.

The silicon oxide SiO₂ material or layer may, for example, be deposited at low pressure, for example, based on the known LPCVD TEOS (tetraethyl orthosilicate Si(OC₂H₅)₄)) process. It employs the dissociation of TEOS at low pressure, e.g. 250 mTorr, and at a temperature exceeding 600° C. (>600° C.). The deposition can be expressed as: Si(OC₂H₅)₄→SiO₂+2C₂H₄+H₂O.

The (copper) impurity gettering barrier layer 21 forms the (copper) impurity enriched layer or material 21B during heating or annealing of the silicon substrate 3 that transfers (copper) impurities from the silicon substrate 3 to the (copper) impurity gettering barrier layer 21. This forms a (copper) impurity enriched layer or material 21B on the silicon substrate 3. The (copper) impurity gettering barrier layer 21 includes or contains the (copper) impurity enriched layer or material 21B. The (copper) impurity enriched layer or material 21B is formed on the substrate 3 prior to fabrication of photonic or optical devices such as optical waveguide devices.

The impurity gettering barrier layer 21 acts as an impurity gettering material or layer, and also an impurity barrier material or layer that can prevent (copper) impurity displacement to layers of materials located further away from the silicon substrate 3 than the impurity gettering barrier layer 21 and located on an opposite side of the impurity gettering barrier layer 21 to that of the silicon substrate 3, in particular, layers or materials of forming photonic or optical devices that are subsequently fabricated.

Heating or annealing is carried out as previously described in relation to the previous embodiment illustrated in FIGS. 1A and 1B.

The silicon oxide layer 29 is deposited to have a thickness greater than that of the copper impurity gettering barrier layer 21. The thickness is, for example, between 1 μm and 10 μm, for example, 4 μm.

Following heating or annealing, an exposed outer surface 37 of the silicon oxide layer 29 is polished (FIG. 2C). Polishing reduces the thickness of the deposited and annealed the silicon oxide layer 29. Polishing is, for example, carried out using the chemical-mechanical polishing CMP previously described herein in relation to the previous embodiment illustrated in FIGS. 1A and 1B. However, other known polishing processes may alternatively or additionally be used.

The polished silicon oxide layer 29 may, for example, have a thickness that is between 10% and 95 % the originally deposited thickness. For example, an originally deposited thickness of 4 μm is polished to remove the deposited and annealed the silicon oxide layer 29 to a thickness of 400 nm.

The polishing silicon oxide surface is of relatively higher quality and provides better surface quality for further depositions.

The silicon oxide layer 29 provided on the silicon substrate 3 is polished to provide at least one polished silicon oxide surface 31 (see for example FIG. 2D). The silicon oxide layer 29 is provided or deposited on the silicon substrate 3 (and on the impurity gettering barrier layer 21) prior to heating or annealing of the silicon substrate 3. The silicon oxide layer 29 is heated or annealed during the formation of the (copper) impurity enriched layer or material 21B

At least one further silicon oxide layer 17 is provided or deposited onto the polished silicon oxide surface 31. The deposited thickness is, for example, between 1 μm and 10 μm, for example, 4 μm. This further silicon oxide layer 17 located above or on the impurity gettering barrier layer 21 acts as an additional or secondary impurity barrier layer to prevent impurities such as copper diffusing or displacing to outer layers of materials located further away from the silicon substrate 3 than the impurity gettering barrier layer 21 and located on an opposite side of the impurity gettering barrier layer 21 to that of the silicon substrate 3, in particular, layers or materials of forming photonic or optical devices that are subsequently fabricated. Layers or materials that are deposited and/or processed to form photonic or optical devices that are subsequently fabricated, are located at a distance from the silicon substrate 3 with the impurity gettering barrier layer 21, the polished silicon oxide layer 29 and the further silicon oxide layer 17 being located between the silicon substrate 3 and the fabricated photonic or optical devices. This prevents or significantly reduces the propagation or diffusion of impurities such as copper to the materials or layers of the photonic device, such as the waveguide core material, and the surrounding cladding materials or layers, such as a lower cladding material or layer and an opposite passivation/cladding layer.

The provision or deposition of the further silicon oxide layer 17 provide a device fabrication structure or substrate 3A (FIG. 2E) that can be used for the fabrication of one or more photonic devices, or photonic waveguide devices.

The further silicon oxide layer 17 (or a portion thereof) may, for example, form part of such photonic devices as for example shown in the embodiment of FIG. 2A. Alternatively, or additionally, further layers or materials are deposited on the further silicon oxide layer 17 and processed to form such photonic devices.

The (copper) impurity gettering barrier layer 21 is configured to prevent impurities such as copper being transferred from the substrate 3 through the impurity gettering barrier layer 21 to the further silicon oxide layer (17) deposited on the polished silicon oxide surface 31.

One or more photonic or optical devices 15 may be fabricated as previously described herein in relation to the previous embodiment illustrated in FIGS. 1A and 1B.

The impurity barrier layer or material 21 is, for example, provided or deposited on the substrate 3 prior to the provision or deposition of one or more photonic or optical device materials on the substrate 3, such materials being used to define a photonic or optical device 15, or an active region thereof, or used to form a waveguide core or elongated waveguide core 19 or a directly waveguide core contacting cladding material 17 of a waveguide structure of the optical or photonic device 15.

After provision of the impurity barrier layer or material 21, one or more photonic or optical device materials can be deposited onto the impurity barrier layer or material 21 to fabricate one or more photonic or optical devices 15, or to fabricate one or more photonic integrated circuits or optical chips 15.

For example, at least one cladding material 17 may be provided or deposited to form a cladding layer of a photonic device 15. At least one waveguide core material 19 may be provided or deposited to form a waveguide or waveguide core 19 embedded in the cladding layer 17.

For example, a cladding material 17 such as SiO₂ may be deposited onto the impurity barrier layer or material 21, structured or patterned, and silicon nitride Si₃N₄ then deposited onto the structured or patterned as SiO₂ as a waveguide core material 19. After removal of excess silicon nitride Si₃N₄ by, for example, planarization, further cladding material can optionally be deposited on top of the waveguide core material 19. Annealing may then be carried out to remove other impurities, such as hydrogen. Alternatively, a silicon nitride Si₃N₄ layer can be deposited on the cladding material 17 and patterned by photolithography to form one or more silicon nitride waveguides and further silicon oxide cladding material can be deposited on top of the patterned silicon nitride waveguide core material 19.

Optical waveguide devices 15 can be fabricated on the impurity barrier layer or material 21, using the Damascene process for example, as described in U.S. Pat. No. 10,191,215 and in the previous references mentioned herein, the entire contents of each of which are incorporated herein by reference.

The optical waveguide or optical waveguide structure fabrication process described herein in relation to the embodiment of FIGS. 13 to 15 can also be used to fabricate optical waveguides or optical waveguide structures as part of an optical device, optical waveguide device, or photonic integrated circuit optical waveguide device preparation or fabrication method.

The present disclosure also concerns at least one photonic device, photonic chip or optical waveguide formed or fabricated on the on the impurity barrier layer or material 21 and substrate 3.

The at least one photonic device, photonic chip or optical waveguide formed or fabricated on the impurity barrier layer or material 21 has, for example, an average copper impurity quantity or concentration of less than 1×10¹⁷ atoms per cm², or less than 0.5×10¹⁷ atoms per cm², or less than 0.1×10¹⁷ atoms per cm².

FIG. 11A shows further details of the substrate preparation method of FIGS. 2A to 2E, and FIG. 11B shows a SIMS measurement of a structure or chip fabricated according to the method of FIGS. 2A and 11, in which a silicon nitride gettering barrier layer 21 is provided below a thicker silicon oxide layer 29, which is used in the preparation of Si₃N₄ photonic devices, and shows an increased level of copper in the gettering barrier layer 21 but not in the Si₃N₄ photonic device.

As illustrated in FIG. 11A, a 200 nm silicon nitride gettering-barrier layer is deposited (step 01) on a bare silicon wafer 3, which is then covered with a thick silicon-oxide layer of 4 μm (step 02). After annealing at 1200° C. for 33 hours, the copper diffuses into the silicon nitride layer 21 from the silicon wafer 3 (step 03). Following polishing (step 04), a high-quality silicon oxide layer is deposited and the resulting gettered wafer is used for standard device production.

The quality of the polishing is high on silicon oxide and provides better surface quality for further depositions. Moreover, the thick oxide at 4 μm (HTO) above the silicon nitride barrier 21 acts as a further stopping-gettering layer to prevent copper diffusing to the silicon nitride layers of the silicon nitride devices on the top (FIG. 11B), which are fabricated and used as the photonic devices. FIG. 11B shows the standard SIMS measurement performed on the photonics chip fabricated. Due to the sputtering through the thick oxide layers, the Si₃N₄ signature signal, represented by the nitrogen count in the 200 nm layer is not reaching steady state, which means that no absolute number for copper concentration can be derived from this measurement. Nevertheless, a clear peak in the copper concentration signifies the presence of the contaminant and an increased level of copper in the gettering barrier layer 21 but not in the Si₃N₄ photonic device. The method of the present disclosure thus assures the provision of optical devices of lower optical loss.

FIG. 2F shows yet another exemplary embodiment of the substrate preparation method according to the present disclosure in which implements backside gettering. The method is identical to that previously described and illustrated in FIGS. 2A to 2E. Additionally, at least one further copper impurity gettering and/or barrier layer 33 is provided on the silicon substrate 3 on a side S1 thereof located opposite the side S2 upon which the impurity gettering barrier layer 21 and/or the further silicon oxide layer 17 is deposited (FIG. 2F).

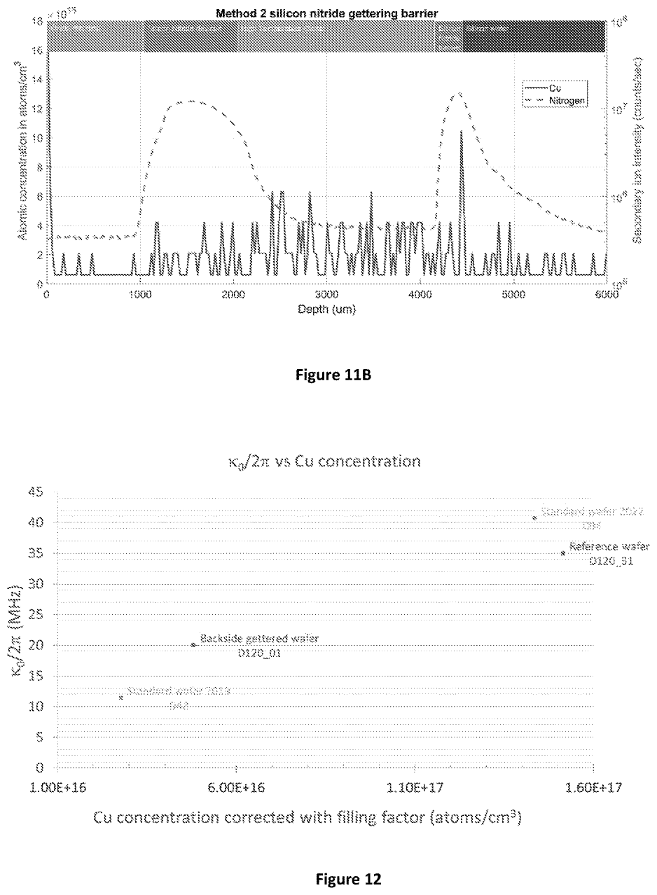

During deposition of the impurity gettering barrier layer 21, the further copper impurity gettering and/or barrier layer 33 (for example, silicon nitride or a phosphor doped layer or material)) is deposited, that is a deposition is carried out on the front and the backside of the silicon wafer or substrate 3. The backside layer 33 acts as a gettering layer for the substate or wafer 3, as the impurity diffusion is faster thereto than through the already deposited thick further silicon oxide 17 on the frontside. FIG. 12 shows the reduced optical loss in waveguide devices fabricated on the decontaminated substate produced by the backside gettering method. The present disclosure also concerns an optical device, optical waveguide device, or photonic integrated circuit optical waveguide device preparation or fabrication method using the substrate or support provided by this substrate or support layer preparation method.

The above-described embodiments concern photonic device substrate or photonic integrated circuit substrate preparation methods. The photonic device substrate or photonic integrated circuit substrate preparation method is, for example, in a preferred embodiment, a photonic silicon nitride optical waveguide device substrate or photonic silicon nitride optical waveguide integrated circuit substrate preparation method. The photonic silicon nitride optical waveguide device substrate or the photonic silicon nitride optical waveguide integrated circuit substrate preparation method is for reducing optical loss in a silicon nitride optical waveguide to be fabricated on the photonic silicon nitride optical waveguide device substrate or the photonic silicon nitride optical waveguide integrated circuit substrate.

The photonic device substrate or the photonic integrated circuit substrate preparation method is, for example, for fabricating an impurity-reduced or a copper impurity reduced photonic integrated circuit or optical waveguide device or devices.

FIGS. 13A to 13C show yet a further aspect of the present disclosure.

FIGS. 13A to 13C show an exemplary embodiment of an optical device, optical waveguide device or photonic integrated circuit optical waveguide device 101 preparation or fabrication method.

The exemplary embodiment is an optical device, optical waveguide device or photonic integrated circuit optical waveguide device 101 preparation or fabrication method for, for example, reducing metal impurity optical loss, transitional metal impurity optical loss or copper impurity optical loss in a waveguide core 115 of an (elongated) optical waveguide 111 or an (elongated) optical waveguide structure 111B of the optical device or of the device 101, for example, optical loss in a silicon nitride waveguide core 115 of the optical waveguide 111 of the optical waveguide device 101.

The method is, for example, a photonic integrated circuit optical waveguide device 101 preparation or fabrication method for reducing copper impurity optical loss in at least one optical waveguide or structure 111, 111B of the photonic integrated circuit optical waveguide device 101, the at least one an optical waveguide or structure 111, 111B comprising, for example, a silicon nitride waveguide core 115.

The copper impurities comprise or consist of, for example, copper intrinsically present in the silicon substrate that migrates to the optical waveguide or structure, or the waveguide core during preparation or fabrication of the optical device, optical waveguide device or photonic integrated circuit optical waveguide device 101.

The copper impurities comprise or consist of copper intrinsically present in the silicon substrate 103 and/or comprise or consist of non-semiconductor manufacturing process introduced copper impurities, and/or comprise or consist of copper impurities present in the silicon substrate 103 prior to the fabrication or provision of a target silicon supported or mounted device that is the at least one optical waveguide 111 or optical waveguide structure 111B. The fabrication process or steps of the at least one optical waveguide 111 or optical waveguide structure 111B does not introduce the copper impurities, copper impurities are present in the provided silicon substrate 103. The provided silicon substrate 103 is the source of copper impurities that diffuse or migrate out of the silicon substrate 103 and to or towards the optical devices that are the at least one optical waveguide 111 or optical waveguide structure 111B.

The method comprises providing at least one substrate or support layer 103, for example, a silicon substrate or support layer 103 (see, for example, FIG. 13A). The substrate or support layer 103 may comprise or consist of the same exemplary material of the substrate or support layer 3 described previously herein in respect to other embodiments.

The silicon substrate 103 may comprise or consist of, for example, a non-reclaimed silicon substrate and/or a device-free silicon substrate and/or an electronic device-free silicon substrate and/or an optical waveguide-free silicon substrate and/or an optical device-free silicon substrate.

The silicon substrate 103 may comprise or consist of, for example, a prime grade silicon wafer or substrate.

The supporting layer or substrate 103 may, for example, comprise or consist of silicon such as a (commercial 4-inch) silicon wafer with, for example, a (for example 4-micron thick) wet thermal oxide, the wet thermal oxide forming the silicon oxide cladding material or layer 107.

The silicon substrate 103 is a contaminated silicon substrate or is a contaminated silicon substrate containing copper impurities. The substrate 103 comprises or consists of, for example, copper contaminated silicon, or silicon containing Cu impurities.

The method comprises providing or depositing at least gettering layer or material 105 or copper gettering layer or material 105, for example, at least one copper gettering silicon nitride layer or material 105 on the silicon substrate 103 (see, for example, FIG. 13A).

Although the present example specifically describes a gettering silicon nitride layer or material 105, the gettering layer or material 105 may comprise or consist of the same exemplary material of the gettering layer or material 9 described previously herein in respect to other embodiments. The thickness of the gettering layer or material 105 can also be the same as that previously described for the gettering layer or material 9. For example, the thickness can be between 150 nm and 450 nm (extremity values included), for example, 200 nm.

Silicon nitride can be deposited, for example, by low-pressure chemical vapor deposition (LPCVD) or plasma-enhanced low-pressure chemical vapor deposition as known to the skilled person (see, for example, Jaeger, Richard C. (2001), “Thermal Oxidation of Silicon”. Introduction to Microelectronic Fabrication, Upper Saddle River: Prentice Hall, ISBN 978-0-201-44494-0, the entire contents of which are incorporated herein by reference). In an exemplary embodiment, a Si₃N₄ layer is deposited via LPCVD from dichlorosilane and ammonia gas precursors at 770° C. in a single deposition run up to the desired thickness.

In a preferred embodiment, the gettering layer or material 105 may, for example, be provided or deposited directly on the substrate 103, or directly onto an exposed outer surface 119 of the silicon substrate 103. Alternatively, the gettering layer or material 105 may, for example, be provided or deposited onto an oxide layer, such as a silicon oxide layer, grown, present or deposited onto the substrate 103.

The gettering layer or material 9 is provided or deposited on the substrate 103 prior to the provision or deposition of one or more photonic or optical device materials 107, 109, 117 onto the substate 103 that are used to define or form a photonic or optical waveguide 111 or used to form the waveguide core 115 or a directly contacting cladding material of a waveguide structure 111 of the optical or photonic device 101.

The method further comprises providing or depositing at least one optical waveguide cladding layer or material 107 or at least one oxide layer or material 107 (for example, directly) on the copper gettering silicon nitride layer or material 105 that is deposited on the silicon substrate 103 (see, for example, FIG. 13B).

The at least one optical waveguide cladding layer or material 107 may comprise or consist of the cladding material 17 described previously herein in respect to other embodiments, for example, the optical waveguide cladding layer or material 107 may comprise or consist of silicon oxide in a preferred embodiment. The cladding material or layer may comprise or consist of oxide materials such as TeO₂ or Al₂O₃, or of one or more polymers. This is also the case for other embodiments described previously in the present disclosure.

Silicon oxide may be deposited onto the substrate 103 to form the cladding material or layer 107 comprising or consisting of silicon dioxide (SiO₂). Deposition may be carried out, for example, by low-pressure chemical vapor deposition (LPCVD) to deposit for example 3 microns of SiO₂ onto the supporting layer or substrate 103.

The silicon oxide SiO₂ cladding material or layer 107 may be deposited at low pressure, for example, based on the known LPCVD TEOS (tetraethyl orthosilicate Si(OC₂H₅)₄)) process. It employs the dissociation of TEOS at low pressure, e.g. 250 mTorr, and at a temperature exceeding 600° C. (>600° C.). The deposition can be expressed as: Si(OC₂H₅)₄→SiO₂+2C₂H₄+H₂O.

The silicon oxide layer 107 may, for example, be a thermal oxide layer produced by oxidation of silicon atoms on an upper portion of the silicon substrate 103 which are converted to silicon oxide, as classically known to the skilled person (see, for example, Jaeger, Richard C. (2001), “Thermal Oxidation of Silicon”. Introduction to Microelectronic Fabrication, Upper Saddle River: Prentice Hall, ISBN 978-0-201-44494-0, the entire contents of which are incorporated herein by reference).

The optical waveguide cladding layer or material 107 is, for example, deposited to have a thickness greater than gettering layer or material 105. The thickness is, for example, between 1 μm and 10 μm, for example, 3 μm.

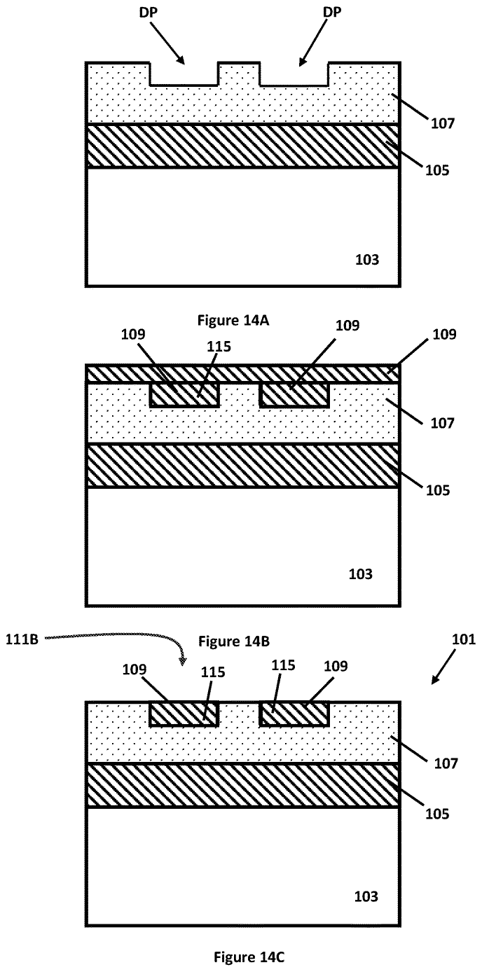

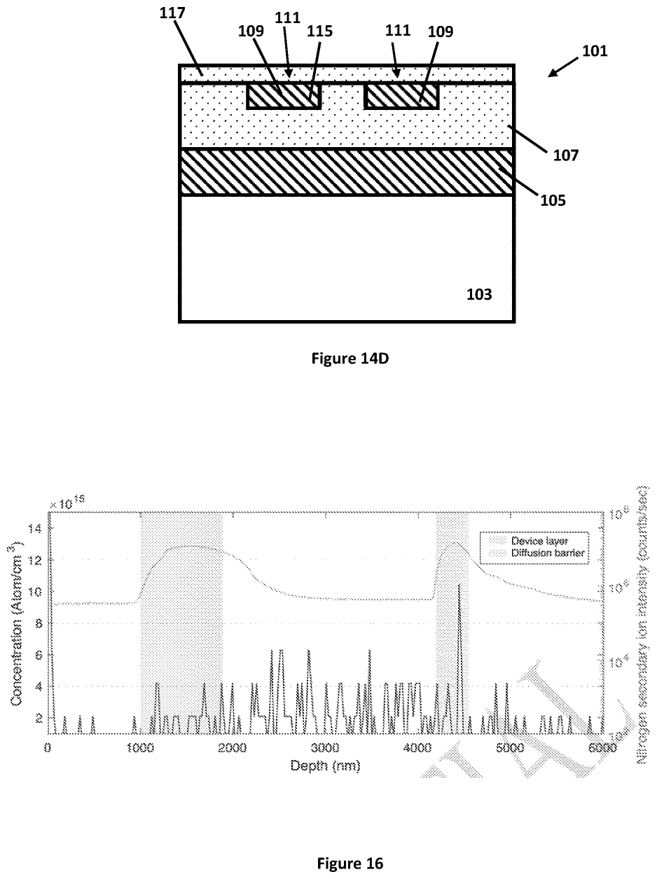

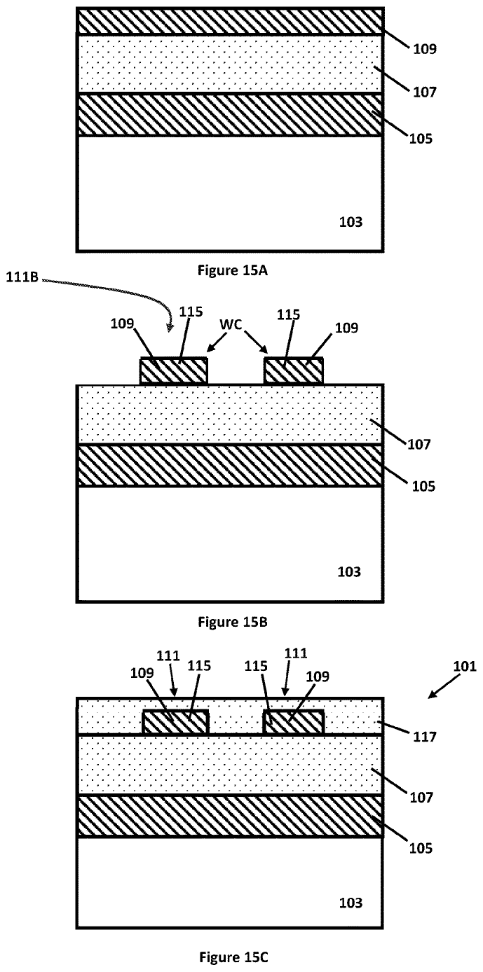

At least one or a plurality of optical waveguides 111 is formed (see, for example, FIG. 13C). At least one or a plurality of optical waveguides structures 111B is, for example formed (see, for example, FIGS. 14C and 15B, 15D). The optical waveguides structures 111B can be intermediate structures of the optical waveguides 111. The optical waveguides structures 111B can nevertheless be optical waveguides. These optical waveguides structures 111B can, for example, also function to propagate and guide light longitudinally through the waveguide core 115. It being, nevertheless, noted that the increased or full cladding enclosed optical waveguides 111 assure relatively lower light loss.

The or each optical waveguide 111 or optical waveguide structure 111 comprises at least one (elongated) waveguide core 115 provided on and supported by the optical waveguide cladding layer or material 107 that is deposited on the copper gettering silicon nitride layer or material 105 which is deposited on the silicon substrate 103. This forms the optical waveguide structure 111B, as shown for example, in FIG. 15B.

The elongated waveguide core 115 may, for example, be at least partially embedded by the optical waveguide cladding layer or material 107 (see, for example, FIG. 14C) to form the optical waveguide structure 111B, or be at least partially embedded by at least one further cladding material or layer 117 provided or deposited (for example, directly) on the optical waveguide cladding layer or material 107 to form an optical waveguide structure 111B (see, for example, FIG. 15D, page 4/14), or be fully embedded by the further cladding material or layer 117 provided or deposited (for example, directly) on the optical waveguide cladding layer or material 107 and the elongated waveguide core 115 to form the optical waveguide 111 (see, for example, FIG. 15C).

The formation of the at least one or the plurality of optical waveguides 111 or optical waveguide structures 111B includes depositing or providing (for example, directly) at least one waveguide core layer or material 109, for example waveguide core silicon nitride layer or material, on the optical waveguide cladding layer or material 107 that is deposited on the copper gettering silicon nitride layer or material 105 which is deposited on the silicon substrate 103.

The optical waveguide core layer or material 109 may, for example, comprise or consist of the same exemplary material described previously with respect to the waveguide core layer or material 19 of previous embodiments. That is, the optical waveguide core layer or material 109 may, for example, comprise or consist of silicon nitride (for example, Si₃N₄), rare earth ion implanted silicon nitride, for example, erbium-doped silicon nitride (for example, Er:Si₃N₄), lithium niobate LiNbO₃ or barium titanate BaTiO₃.

The optical waveguide core layer or material 109 may have a thickness that is, for example, between 10 nm and 2 μm, for example, 0.7 μm. The elongated waveguide core 115 may have a thickness that is, for example, between 10 nm and 1.2 μm. The elongated waveguide core 115 may have a width that is, for example, between 250 nm and 3 μm, for example, 2 μm. The elongated waveguide core may, for example, extend over a distance, for example, between 0.1 m and 0.6 m. The recess or depression DP that contains the optical waveguide core layer or material 109 has, for example, the same dimensions. This is equally the case for other embodiments of the present disclosure.

The optical waveguide 111 may, for example, be formed by structuring the optical waveguide cladding layer or material 107 to include or define at least one or a plurality of elongated depressions or recesses DP (see, for example, FIGS. 14A to 14D). The depressions or recesses DP and the optical waveguides 111 may, for example, be formed or provided using the Damascene process, for example, as described in previously mentioned U.S. Pat. No. 10,191,215. The waveguide core silicon nitride layer or material 109 is provided or deposited (for example, directly) onto and/or into the one or more elongated depressions or recesses DP or on a surface defines by the depression or recess DP. This forms elongated waveguide cores 115 that are at least partially embedded in the optical waveguide cladding layer or material 107 and supported by or on the optical waveguide cladding layer or material 107, to form for example the optical waveguide structure 111B (see, for example, FIG. 14C). Excess waveguide core silicon nitride layer or material 109 can be removed, for example, by chemical-mechanical polishing or etching, a thin layer may nevertheless remain across the optical waveguide cladding layer or material 107.

At least one passivation or further cladding layer or material 117 may optionally be provided or deposited (for example, directly) on the optical waveguide cladding layer or material 107 and/or on the waveguide core silicon nitride layer or material 109 that is deposited on the optical waveguide cladding layer or material 107. The cladding layer or material may be provided or deposited on the waveguide core silicon nitride layer or material 109 contained in the depressions DP or on the elongated waveguide cores 115. This forms an elongated waveguide cores 115 that is fully enclosed by cladding material (see, for example, FIG. 14D).

The passivation or cladding layer or material 117 can comprise or consist of the same material as that of the optical waveguide cladding layer or material 107. The further cladding material or layer 117 may have, for example, a thickness for example, between 1 μm and 10 μm, for example, 2 μm. In a preferred embodiment, the passivation or cladding layer or material 117 may comprise or consist of silicon oxide.

The silicon dioxide (SiO₂) layer or material of the passivation or cladding layer or material 117 can, for example, be deposited by plasma-enhanced chemical vapor deposition PECVD using precursors comprising, for example, silicon tetrachloride SiCl₄ and an oxidizer, for example, oxygen O₂ and/or nitrous oxide N₂O. Argon (Ar) gas may, for example, also be used during deposition. The plasma is an inductively coupled plasma ICP. An ICP power source generates a plasma or high-density plasma through inductive coupling between a radio frequency (RF) antenna and the plasma. An induction coil is excited or powered by an RF power source or voltage generator, and the plasma is generated by coupling energy to the plasma through the generation of a magnetic field by the RF power source passing a high frequency current through the induction coil. The bias radiofrequency power is between 180W and 400W. The ICP excitation power is greater than or equal to 1600W. The silicon dioxide (SiO₂) layer or material is deposited by inductively coupled plasma plasma-enhanced chemical vapor deposition ICP-PECVD using a plasma-enhanced chemical vapor deposition ICP-PECVD tool or reactor (see for example, Zheru Qiu, et al., “Low-temperature and hydrogen-free silicon dioxide cladding for integrated photonics,” in CLEO 2023, Technical Digest Series (Optica Publishing Group, 2023), paper SM2H.2, the entire contents of which are fully incorporated herein by reference).

The passivation or further cladding layer or material 117 may be provided or deposited on the optical waveguide cladding layer or material 107 and/or on the waveguide core silicon nitride layer or material 109 that is deposited on the copper gettering silicon nitride layer or material 105 which is deposited on the silicon substrate 103.

Alternatively, the optical waveguide 111 or the optical waveguide 111B may be formed by providing or depositing at least one waveguide core silicon nitride layer or material 109 on the optical waveguide cladding layer or material 107, and structuring the waveguide core silicon nitride layer or material 109 (see, for example, FIGS. 15A to 15C).

The waveguide core silicon nitride layer or material 109 can, for example, be structured to form one or more elongated waveguide cores 115 (see, for example, FIG. 15B).

A hard mask is provided or formed on the waveguide core silicon nitride layer or material 109 which allows the elongated waveguide cores 115 to be formed or defined (see, for example, FIG. 15B). The hard mask includes at least one or a plurality of recesses or openings defining or delimiting a mask pattern. The pattern allows to form, in the deposited the waveguide core silicon nitride layer or material 109, the one or more elongated waveguide cores 115.

The hard mask is formed from a hard mask layer comprising or consisting of, for example, amorphous silicon aSi. The amorphous silicon aSi layer (of for example 300 nm thickness) may, for example, be deposited by low-pressure chemical vapor deposition (LPCVD) onto the waveguide core silicon nitride layer or material 109. Amorphous silicon aSi is provided as an exemplary material for forming the hard mask. The hard mask layer may alternatively comprise or consist of, for example, silicon oxide SiO₂, or diamond-like carbon (DLC).

The hard mask is then formed or defined in the aSi hard mask layer, for example, using deep ultra-violet photolithography (ASML PAS 5500/350C stepper, JSR M108Y resist, and Brewer DUV-42P coating).

The pattern(s) is defined using, for example, DUV lithography into a resist coating provided or deposited on the aSi hard mask layer.

Photolithography or UV lithography can used to transfer the (geometric) pattern or structure to the deposited aSi hard mask layer or material. Deep ultraviolet (DUV) photolithography using, for example, light of wavelength <400 nm, for example, in the range 193 nm-254 nm illuminates the photomask to define an exposure pattern on and in the deposited aSi hard mask layer or material such that the resulting pattern formed on the aSi hard mask layer or material can then be transferred into the underlying waveguide core silicon nitride layer or material 109.

The exposed resist of the resist coating is removed, for example, by development as is well known to the skilled person in the art. This can, for example, be done using a TMAH photoresist developer, which for example, is commercially available from the company JSR. The resulting pattern(s) is then transferred into the underlying and exposed aSi hardmask layer using, for example, a silicon dry etch (for example based on SF₆ and C₄F₈) to form the hard mask. The resist mask is subsequently stripped off.

The exposed and/or underlying waveguide core silicon nitride layer or material 109 is then removed. The (geometric) pattern or structure of the hard mask is transferred from the hard mask to the exposed and/or underlying the waveguide core silicon nitride layer or material 109. This is done, for example, by dry or wet etching.

Dry etching, or reactive ion etching or plasma etching of the waveguide core silicon nitride layer or material 109 to form the one or more silicon nitride elongated waveguide cores 115 (see, for example, FIG. 15B) may comprise, for example, carrying out anisotropic dry etching carried out using, for example, CₓF_{y}-based chemical substances. Oxygen, may, for example, be added in order to remove CF polymers created as an etching by-product. Etching can, for example, be carried out with CHF₃ and SF₆, and with O₂ also, serving to remove the etching by-product from chemical reactions between Si₃N₄ and CHF₃/SF₆.

As seen in FIG. 15B, this forms the elongated waveguide cores 115. Etching is, for example, performed to remove the silicon nitride material to expose the surface of the underlying supporting cladding material or layer 107.

In the case of amorphous silicon aSi as the hard-mask, the remaining hard-mask material is, for example, stripped in concentrated KOH solution at, for example, 60° C. This exposes the surface of the silicon nitride material or layer 109 or the elongated waveguide cores 115.

Structuring the waveguide core silicon nitride layer or material 109 forms at least one elongated waveguide core ridge or protrusion 115.

Similarly, at least one passivation or further cladding layer or material 117 may optionally be provided or deposited (for example, directly).

The elongated waveguide core 115 may, for example, be at least partially embedded by at least one further cladding material or layer 117 provided or deposited (for example, directly) on the optical waveguide cladding layer or material 107 to form an optical waveguide structure 111B (see, for example, FIG. 15D), or be fully embedded by the further cladding material or layer 117 provided or deposited (for example, directly) on the optical waveguide cladding layer or material 107 and the elongated waveguide core 115 to form the optical waveguide 111 (see, for example, FIG. 15C).

The copper gettering silicon nitride layer or material 105 is internally located between (i) the silicon substrate or support 103 and (ii) the deposited or provided waveguide core silicon nitride layer or material 109 and/or the deposited or provided optical waveguide cladding layer or material 107. This captures or traps copper impurities migrating or diffusing from the silicon substrate or support 103 to prevent the copper impurities migrating or diffusing to optical waveguides 111 or optical waveguide structures 111B.

The optical waveguides 111 or optical waveguide structures 111B are located in a device region or optical device region AR. The copper gettering silicon nitride layer or material 105 is internally located between (i) the silicon substrate or support 103 and (ii) the optical device region. Copper impurities migrate or diffuse from the silicon substrate or support 103 towards the optical device region, and the inner located or intermediate copper gettering silicon nitride layer or material forms a barrier to copper migration to the optical device region.

The gettering layer or material 105 extends to define a supporting impurity or copper barrier layer or material that supports the one or more optical waveguides 111 or one or more optical waveguide structures 111B.

The gettering layer or material 105 is superposed on the silicon substrate or support 103 and extends underneath or vertically underneath the at least one optical waveguides 111 or optical waveguide structure 111B. The gettering layer or material 105 extends, for example, underneath or vertically underneath at least the full width w of the at least one optical waveguides 111 or optical waveguide structure 111B, or of each optical waveguide 111 or optical waveguide structure 111B. The gettering layer or material 105 extends, for example, underneath or vertically underneath at least the full width w of each optical waveguide 111 or optical waveguide structure 111B, and between optical waveguides 111 or optical waveguide structures 111B. The vertical direction (y-direction) being perpendicular to the elongated plane defined by the silicon substrate or support 103.

Copper impurities migrate or diffuse from the silicon substrate or support 103. Copper impurities migration or diffusion is, for example, non-device active region migration or diffusion of copper impurities, or non-optical waveguide migration or diffusion of copper impurities, or non-optical waveguide structure migration or diffusion of copper impurities.

Other elements or optical elements may be provided or included in or on the device 101. For example, one or more metallic heaters by be deposited superposed on a portion of the elongated waveguide core(s) 115, for example, provided or deposited on the passivation or further cladding layer or material 117.

Advantageously, annealing or heating of the silicon substrate or support 103 (and structure/optical devices and/or layers formed or provided thereon) may, for example, be carried out after the formation of optical waveguide(s) 111 and/or optical waveguide structure(s) 111B. This permits to remove hydrogen impurities or hydrogen-related impurities from the optical waveguide(s) 111 and/or optical waveguide structure(s) 111B, or the constituent materials thereof. This simultaneously permits to capture or trap or acquire migrating copper impurities of the silicon substrate 103 (or that migrate from the silicon substrate 103 towards or in the direction of the optical waveguide(s) 111 and/or optical waveguide structure(s) 111B) in the copper gettering silicon nitride layer or material 105.

Advantageously, the method comprises annealing or heating of the silicon substrate 103, for example, after forming the one or more optical waveguides 111 and/or the optical waveguide structure(s) 111B including the elongated waveguide core 115 provided on and supported by the optical waveguide cladding layer or material 107, and/or at least partially embedded by the optical waveguide cladding layer or material 107 (see, for example, FIGS. 14C and 15B).

Advantageously, the method comprises annealing or heating of the silicon substrate 103, for example, after forming the one or more optical waveguides 111 including the elongated waveguide core 115 fully embedded in cladding material by at least one further cladding material or layer 117 provided or deposited on the optical waveguide cladding layer or material 107 (see, for example, FIG. 14D); or after forming the one or more optical waveguide structures 111B including the elongated waveguide core 115 at least partially embedded by the further cladding material or layer 117 provided or deposited on the optical waveguide cladding layer or material 107 (see, for example, FIG. 15D), or after forming the one or more optical waveguides 111 including the elongated waveguide core 115 fully embedded by the further cladding material or layer 117 provided or deposited on the optical waveguide cladding layer or material 107 and on the at least one elongated silicon nitride waveguide core 115 (see, for example, FIG. 15C).

The annealing or heating is carried out to remove or reduce, for example, hydrogen impurities or hydrogen-related impurities. Such impurities may for example include light absorbing OH bonds (or Si—OH bonds) that absorb light at one or more wavelengths associated with or in an operational wavelength range of the optical waveguide 111.

Such impurities may for example include excess hydrogen H₂, or Si—H and N—H bonds within the silicon nitride (for example, Si₃N₄) layers or materials, for example, in the waveguide core 115 and/or the waveguide core silicon nitride layer or material 109. The presence of such impurities or contaminants results in optical loss or light loss, for example, in the waveguide core 115 and/or the waveguide core silicon nitride layer or material 109 and their removal or reduction results in lower optical loss.

Annealing permits, for example, to remove or reduce residual hydrogen, break such bonds to provide low or lower loss waveguide devices, or low or lower loss silicon nitride-based PICs.

Additionally, or alternatively, the annealing or heating is carried out to remove or reduce, for example, transition metal impurities or content or copper impurities or content in the optical waveguides 111 or optical waveguide structures 111B. Annealing transfers copper impurities from the silicon substrate 103 towards the optical waveguides 111 or optical waveguide structures 111B and into the at least one copper gettering silicon nitride layer or material 105 where the impurity is captured, acquired or trapped and prevented from migrating to the optical waveguides 111 or optical waveguide structures 111B.

The resulting device 101 contains optical waveguides 111 or optical waveguide structures 111B located or superposed on a copper enriched copper gettering silicon nitride layer or material 105.

OH bonds can produce a (strong) absorption peak of OH bonds around or extending over the 1380 nm wavelength, with a long absorption tail extending to longer wavelengths.

The absorption or optical loss characteristic peak is in the near-infrared (that is at 1380 nm or about (±5 nm) 1380 nm, or that includes the wavelength of 1380 nm) due to a vibration overtone of OH bonds formed by hydrogen impurity trapped in the deposited silicon-based layer or film.

This optical absorption or absorption peak originates typically from the hydrogen impurity introduced by the commonly used silicon precursors, such as SiH₄, SiH₂Cl₂, and Si(OC₂H₅)₄ (TEOS) and used during deposition processes (for example in chemical vapor deposition processes).

This occurs, for example, during silicon oxide (SiO₂) deposition for cladding material deposition, such as during the provision of the optical waveguide cladding layer or material 107 and/or the further cladding material or layer 117.

This optical absorption or absorption peak is shifted or removed, or (significantly/substantially) reduced by annealing.

Additionally, or alternatively, annealing or heating of the silicon substrate 103 may be carried out, for example, after depositing the optical waveguide cladding layer or material 107 on the copper gettering silicon nitride layer or material 105 that is deposited on the silicon substrate 103. Annealing or heating of the silicon substrate 103 can be carried out, for example, after depositing the optical waveguide cladding layer or material 107 on the copper gettering silicon nitride layer or material 105 that is deposited on the silicon substrate 103, and before the formation of the optical waveguide 111 and/or the deposition or provision of the waveguide core layer or material 109 on the optical waveguide cladding layer or material 107.

Annealing or heating of the silicon substrate 103 may be carried out, for example, after deposition or provision of the further cladding material or layer 117, for example, after deposition on the optical waveguide cladding layer or material 107, or after deposition on the optical waveguide cladding layer or material 107 and on the waveguide core layer or material 109 or the elongated waveguide core 115.

Additionally, or alternatively, annealing or heating of the silicon substrate 103 can be carried out, for example, after deposition of the copper gettering silicon nitride layer or material 105 on the silicon substrate or support 103. Annealing or heating of the silicon substrate 103 can be carried out, for example, after deposition of the copper gettering silicon nitride layer or material 105 on the silicon substrate or support 103, and before provision or deposition of the optical waveguide cladding layer or material 107 on the copper gettering silicon nitride layer or material 105. This allows metal impurities such as copper to already be captured by the copper gettering silicon nitride layer or material 105 prior to formation of the optical waveguide(s) 111.

In the case where the waveguide core layer or material 109 or the elongated the waveguide core 115 is implanted or doped with rare earth ions (for example, with Er ions), the above-mentioned impurity annealing can for example be carried out after implantation. This may alternatively be done prior to implantation. In such a case, a post implantation annealing may also be carried out, for example, at 1000° C.

Annealing or heating can be carried in the same manner described previously in relation to other exemplary embodiments of the present disclosure.

The heating or annealing of the substrate 103 (and supporting layers/materials or optical waveguide(s) 111) can, for example, be carried out by heating of the substrate 103 in an oven or furnace, for example, in a controlled atmosphere, for example, a nitrogen atmosphere. However, different methods can be used, for example, annealing in a chlorine atmosphere.

The substrate 103 is maintained in the oven at a temperature and for a time duration that, for example, permits impurity displacement or diffusion from the substrate 103 and to or into the copper gettering silicon nitride layer or material 105. For example, annealing after deposition of the copper gettering silicon nitride layer or material 105 on the silicon substrate or support 103, and before provision or deposition of the optical waveguide cladding layer or material 107 on the copper gettering silicon nitride layer or material 105 may for example be carried out for a duration of 4 hours at a temperature of, for example, 1000° C. The temperature may, for example, be ramped up to 1000° C. at a 10° C./min ramping rate.

When annealing is performed to remove hydrogen impurities or hydrogen-related impurities (for example, from the optical waveguide 111 or optical waveguide structure 111B (or its constituent materials or layers formed on the substrate 103) and to capture metal or copper impurity displacement or diffusion from the substrate 103 and to or into the copper gettering silicon nitride layer or material 105, the time duration may be, for example, between 10 and 35 hours, and the annealing temperature may, for example, be 1100° C. or 1200° C. These values can be adjusted in a manner permitting to optimize the impurity extraction (hydrogen impurities or hydrogen-related impurities) or obtain a satisfactory remanent impurity level, and to obtain impurity displacement (for example, copper) to the gettering silicon nitride layer or material 105. The substrate 3 may, for example, be heated or annealed at a temperature between 400° C. and 1200° C., or 400° C. and 1250° C., or between 800° C. and 1200° C. or 800° C. and 1250° C. (extremity value included). The substrate 3 may, for example, be heated or annealed for a time duration between 1 hour and 12 hours, or between 1 hour and 35 hours or between 8 hours and 15 hours for any one of the previous temperature ranges. The extremity values being included in the range. For example, at 1200° C. for 11 hours.

Annealing may for example, be carried out after providing or depositing the passivation or further cladding layer or material 117 on the waveguide core silicon nitride layer or material 109.

The photonic integrated circuit optical waveguide device 101 comprises the at least one optical waveguide 111 or optical waveguide structure 111B provided on and supported by at least one optical waveguide cladding layer or material 107 that is located on at least one copper gettering silicon nitride layer or material 105 which is located on the silicon substrate 103 is provided for use for guiding light or at least on optical signal.

The at least one copper gettering silicon nitride layer or material 105 is unremoved or permanently remains present (in the device 101) after all optical waveguide 111 or optical waveguide structure 111B fabrication steps have been completed.

The photonic integrated circuit optical waveguide device 101 includes the at least one copper gettering silicon nitride layer or material 105, on the at least one silicon substrate 103, containing copper impurities provided by or from the at least one silicon substrate 103.

The present disclosure also concerns a photonic integrated circuit optical waveguide device 101, or a photonic integrated circuit optical waveguide device 101 produced by the method according to any one of the previous claims, wherein the photonic integrated circuit optical waveguide device 101 includes the at least one copper gettering silicon nitride layer or material 105, on the at least one silicon substrate 103, that contains copper impurities provided by or from the at least one silicon substrate 103, wherein the photonic integrated circuit optical waveguide device 101 includes at least one optical waveguide 111 or optical waveguide structure 111B provided on and supported by at least one optical waveguide cladding layer or material 107 that is located on at least one copper gettering silicon nitride layer or material 105 which is located on the silicon substrate 103.

Keeping unwanted metal impurities such as copper away from the optical device or optical waveguides ensures that the devices work better or at their best and remain reliable. The present method achieves this by applying, for example, a thin silicon nitride (Si₃N₄) layer 105 (~200 nm) onto the silicon wafer 103, for example, directly onto the silicon wafer 103. Subsequently, a bottom cladding layer 107, for example a 3-micron high-temperature oxide film, is incorporated to accommodate devices necessitating, for example, silicon oxide as the cladding material 107. Additional cladding materials 117 can be applied atop the Si₃N₄ diffusion barrier or gettering layer 105 during the device fabrication process.

The method stops the diffusion of metal impurities, which is typically associated with high-temperature fabrication processes, from the silicon base 103 into the active parts of the photonic integrated circuits. The exemplary Si₃N₄ layer 105 serves as a robust barrier, attracting and capturing metal impurities from the silicon substrate, thus mitigating their migration into the optical devices of the PICs. This effectively sequesters metal impurities during high-temperature processes, where their diffusion is notably increased. This integrated approach offers a significant advantage in mass production, and ensures higher purity and performance in photonic devices. This method contrasts with other methods by the absence or the elimination of the step involving a removal of one or more gettering layers designed to extract specific metal impurities. The gettering layer removal often involves chemical wet etching or plasma dry etching, which can degrade the surface roughness This increased roughness will be transferred to, for example, the oxidized SiO₂ surface during the preparation of photonics integrated circuits when SiO₂ is provided as a cladding material. The present method permits to avoid this inconvenience.

The present method also streamlines the device fabrication process, resulting in reduced complexity. Furthermore, the ease of scalability of this method makes it particularly well-suited for high-volume production, facilitating mass manufacturing.

FIG. 16 shows secondary ion mass spectrometry (SIMS) measurements to detect copper (Cu) impurities across different layers of the fabricated device of FIG. 15C. The measurement results show a substantial concentration of Cu in the gettering silicon nitride layer, exceeding the concentration in other device layers by an order of magnitude. This finding highlights the effectiveness of the gettering layer in impurity sequestration and demonstrates the practical application and effectiveness of this approach in reducing metal impurity diffusion in photonic devices.

Implementations described herein are not intended to limit the scope of the present disclosure but are just provided to illustrate possible realizations.

While the invention has been disclosed with reference to certain preferred embodiments, numerous modifications, alterations, and changes to the described embodiments, and equivalents thereof, are possible without departing from the sphere and scope of the invention. Accordingly, it is intended that the invention not be limited to the described embodiments and be given the broadest reasonable interpretation in accordance with the language of the appended claims. The features of any one of the above described embodiments may be included in any other embodiment described herein. Extremity values in ranges are included in the specified range.

1. Method for fabricating a photonic integrated circuit optical waveguide device for reducing copper impurity optical loss in at least one of at least one optical waveguide and at least one optical waveguide structure of the photonic integrated circuit optical waveguide device, the at least one of the at least one optical waveguide (111) and the at least one optical waveguide structure comprising a waveguide core comprising silicon nitride, the method comprising:
providing at least one substrate comprising silicon,
depositing at least one copper gettering layer and/or material comprising silicon nitride on the at least one substrate comprising silicon,
depositing at least one optical waveguide cladding layer and/or material on the at least one copper gettering layer and/or material comprising silicon nitride that is deposited on the at least one substrate comprising silicon,
forming the at least one of the at least one optical waveguide and the at least one optical waveguide structure comprising at least one elongated waveguide core comprising silicon nitride provided on and supported by the at least one optical waveguide cladding layer and/or material that is deposited on the at least one copper gettering layer and/or material comprising silicon nitride which is deposited on the at least one substrate comprising silicon, the at least one elongated waveguide core comprising silicon nitride being supported by and/or being at least partially embedded by the at least one optical waveguide cladding layer and/or material;
and
thermally annealing the at least one substrate comprising silicon after the formation of the at least one of the at least one optical waveguide and the at least one optical waveguide structure on the at least one substrate comprising silicon to remove hydrogen impurities and/or hydrogen-related impurities from the at least one of the at least one optical waveguide and the at least one optical waveguide structure, and to capture or trap copper impurities of the at least one substrate comprising silicon in the at least one copper gettering layer and/or material comprising silicon nitride.

2. Method according to claim 1, wherein the at least one copper gettering layer and/or material comprising silicon nitride is deposited directly onto the at least one substrate comprising silicon.

3. Method according to claim 1, wherein the at least one elongated waveguide core comprising silicon nitride is supported by the optical waveguide cladding layer and/or material, and at least partially and/or fully embedded by at least one further cladding material and/or layer provided or deposited on the at least one elongated waveguide core comprising silicon nitride and on the optical waveguide cladding layer and/or material.

4. Method according to claim 1, including forming at least one of the at least one optical waveguide and the at least one optical waveguide structure by structuring the at least one optical waveguide cladding layer and/or material to include at least one elongated depression, and providing at least one waveguide core layer and/or material comprising silicon nitride in the at least one elongated depression to form at least one elongated waveguide core at least partially embedded in the at least one optical waveguide cladding layer and/or material.

5. (canceled)

6. Method according to claim 1, including forming the at least one of the at least one optical waveguide and the at least one optical waveguide structure by providing at least one waveguide core layer and/or material comprising silicon nitride on the at least one optical waveguide cladding layer and/or material, structuring the at least one waveguide core layer and/or material comprising silicon nitride to form at least one elongated waveguide core, and at least partially embedding the at least one elongated waveguide core in at least one further cladding material and/or layer.

7. Method according to claim 5, wherein structuring of the at least one waveguide core layer and/or material comprising silicon nitride is carried out to form at least one elongated waveguide core ridge, and the at least one further cladding layer and/or material is deposited onto the at least one elongated waveguide core ridge to form the at least one of the at least one elongated optical waveguide and the at least one optical waveguide structure.

8. Method according to claim 4, including providing at least one passivation and/or further cladding layer or material on the waveguide core layer and/or material comprising silicon nitride that is provided on the at least one optical waveguide cladding layer and/or material that is provided on the at least one copper gettering layer and/or material comprising silicon nitride which is provided on the at least one substrate comprising silicon.

9. Method according to claim 1, wherein thermally annealing the at least one substrate comprising silicon after the formation of the at least one of the at least one optical waveguide and the at least one optical waveguide structure is carried out at a temperature between 400° C. and 1200° C., and for a time duration between 1 hour and 35 hours.

10. Method according to claim 1, wherein deposition of the at least one optical waveguide cladding layer and/or material on the at least one copper gettering layer and/or material comprising silicon nitride is carried out by high-temperature low-pressure chemical vapor deposition to deposit the at least one optical waveguide cladding layer and/or material having a greater deposition thickness than that of the at least one copper gettering layer and/or material comprising silicon nitride.

11. Method according to claim 1, wherein deposition of the at least one copper gettering layer and/or material comprising silicon nitride is carried out by plasma-enhanced low-pressure chemical vapor deposition.

12. Method according to claim 1, wherein the at least one copper gettering layer and/or material comprising silicon nitride is internally located between (i) the at least one substrate comprising silicon and (ii) the at least one of the at least one optical waveguide and the at least one optical waveguide structure, and the at least one copper gettering layer and/or material extends underneath the at least one of the at least one optical waveguide and the at least one optical waveguide structure to capture copper impurities migrating and/or diffusing from the substrate comprising silicon and towards the at least one of the at least one optical waveguide and the at least one optical waveguide structure to prevent the copper impurities migrating and/or diffusing to the at least one of the at least one optical waveguide and the at least one optical waveguide structure.

13. Method according to claim 1, wherein thermally annealing the at least one substrate comprising silicon after the formation of the at least one of the at least one optical waveguide and the at least one optical waveguide structure is carried out to remove Si—OH bonds in the at least one of the at least one optical waveguide and the at least one optical waveguide structure.

14. Method according to claim 1, wherein thermally annealing the at least one substrate comprising silicon after the formation of the at least one of the at least one optical waveguide and the at least one optical waveguide structure is carried out to remove Si—H and N—H bonds in the at least one of the at least one optical waveguide and the at least one optical waveguide structure.

15. Method according to claim 1, wherein thermal annealing transfers copper impurities from the at least one substrate comprising silicon towards the at least one of the at least one optical waveguide and the at least one optical waveguide structure and into the at least one copper gettering layer and/or material comprising silicon nitride.

16. Method according to claim 1, wherein the copper impurities comprise copper intrinsically present in the at least one substrate comprising silicon and/or comprise non-semiconductor manufacturing process introduced copper impurities, and/or comprise copper impurities present in the at least one substrate comprising silicon prior to the fabrication of a target substrate supported device that is the at least one of the at least one optical waveguide and the at least one optical waveguide structure.

17. Method according to claim 1, wherein in the providing of the at least one substrate comprising silicon, the provided at least one substrate comprising silicon comprises a non-reclaimed silicon substrate and/or a device-free silicon substrate and/or an electronic device-free silicon substrate and/or an optical waveguide-free silicon substrate.

18. Method according to claim 1, wherein in the providing of the at least one substrate comprising silicon, the provided at least one substrate comprising silicon comprises a prime grade silicon wafer.

19. Method according to claim 1, including providing the photonic integrated circuit optical waveguide device comprising the at least one of the at least one optical waveguide and the at least one optical waveguide structure provided on and supported by at least one optical waveguide cladding layer and/or material that is located on at least one copper gettering layer and/or material comprising silicon nitride which is located on the at least one substrate comprising silicon for use for guiding light and/or guiding at least one optical signal.

20. Method according to claim 1, wherein the photonic integrated circuit optical waveguide device includes the at least one copper gettering layer and/or material comprising silicon nitride, on the at least one substrate comprising silicon, and containing copper impurities provided by and/or from the at least one substrate comprising silicon.

21. Method according to claim 1, wherein the photonic integrated circuit optical waveguide device includes the at least one of the at least one optical waveguide and the at least one optical waveguide structure provided on and supported by at least one optical waveguide cladding layer and/or material that is located on at least one copper gettering layer and/or material comprising silicon nitride which is located on the at least one substrate comprising silicon.

22-47. (canceled)
